(19) United States
(12) Patent Application Publication
(10) Pub. No.: US 2025/0071979 A1
(43) Pub. Date: Feb. 27, 2025

(54) MEMORY DEVICES HAVING VERTICAL TRANSISTORS IN PERIPHERAL CIRCUITS

(71) Applicant: Yangtze Memory Technologies Co., Ltd., Wuhan (CN)

(72) Inventors: Chao SUN, Wuhan (CN); Ning JIANG, Wuhan (CN); Wei LIU, Wuhan (CN)

(21) Appl. No.: 18/477,521

(22) Filed: Sep. 28, 2023

Related U.S. Application Data
(63) Continuation of application No. PCT/CN2023/114355, filed on Aug. 23, 2023.

(51) Int. Cl. H10B 12/00

(52) U.S. Cl. CPC H10B 12/50

(57) ABSTRACT

The present disclosure relates to memory devices and memory systems. An example memory device includes an array of memory cells and a peripheral circuit. Each of the array of memory cells comprises a first vertical transistor and a storage structure coupled to the first vertical transistor in a first direction. The peripheral circuit is adjacent to the array of memory cells in a second direction perpendicular to the first direction. The peripheral circuit includes a second vertical transistor coupled to one of the array of memory cells through the first vertical transistor of the one of the array of memory cells.

### CROSS-REFERENCE TO RELATED APPLICATIONS

This application is a continuation of International Application No. PCT/CN2023/114355, filed on Aug. 23, 2023, the disclosure of which is hereby incorporated by reference in its entirety.

### TECHNICAL FIELD

The present disclosure generally relates to memory devices and memory systems.

### BACKGROUND

Semiconductor industry is driven by the need to produce smaller and faster chips. Makers of memory devices and systems also are pushing to improve scaling techniques. Dynamic random-access memory (DRAM) is a common type of memory device widely used in computer systems. The mainstream DRAM architecture has been using an 8F² cell design and a 6F² cell design for many years and is now in the process of shifting to a 4F² cell design. The scaling of DRAM devices faces many challenges. For example, the fabrication process has advanced from an 18 nanometer (nm) process and a 15 nm process to a 10 nm process. However, the increased density of memory cells in a chip and the Row hammer effect may cause disturbance errors. Therefore, advanced techniques for mitigating these problems and improving the scaling of the DRAM devices are desired.

### SUMMARY

The present disclosure relates to memory devices and memory systems. An example memory device includes an array of memory cells and a peripheral circuit. Each of the array of memory cells comprises a first vertical transistor and a storage structure coupled to the first vertical transistor in a first direction. The peripheral circuit is adjacent to the array of memory cells in a second direction perpendicular to the first direction. The peripheral circuit includes a second vertical transistor coupled to one of the array of memory cells through the first vertical transistor of the one of the array of memory cells.

While generally described as computer-implemented software embodied on tangible media that processes and transforms the respective data, some or all of the aspects may be computer-implemented methods or further included in respective systems or other devices for performing this described functionality. The details of these and other aspects and implementations of the present disclosure are set forth in the accompanying drawings and the description below. Other features, objects, and advantages of the disclosure will be apparent from the description and drawings, and from the claims.

### BRIEF DESCRIPTION OF DRAWINGS

FIG. 1 illustrates a schematic view of a cross-section of a memory device, according to some aspects of the present disclosure.

FIGS. 2A-2B illustrate a schematic diagram of a memory device having vertical transistors, according to some aspects of the present disclosure.

FIG. 3 illustrates a side view of a cross-section of a memory device having vertical transistors, according to some aspects of the present disclosure.

FIG. 4 illustrates a memory device having multiple memory cell arrays, according to some aspects of the present disclosure.

FIG. 5A illustrates a plan view of a memory device having two memory cell arrays, according to some aspects of the present disclosure.

FIG. 5B illustrates a plan view of a memory device having at least one word line driver device, according to some aspects of the present disclosure.

FIG. 6 illustrates a flowchart of a method for forming an array wafer of a memory device, according to some aspects of the present disclosure.

FIGS. 7A-7C illustrate examples of a semiconductor layer with trenches, according to some aspects of the present disclosure.

FIGS. 8A-8D illustrate examples of forming gate structures in a semiconductor layer, according to some aspects of the present disclosure.

FIG. 9 illustrates an example of forming sources and drains for semiconductor bodies in a semiconductor layer, according to some aspects of the present disclosure.

FIGS. 10A-10F illustrate examples of forming storage structures and interconnects in a semiconductor layer, according to some aspects of the present disclosure.

FIG. 11 illustrates a block diagram of a system having a memory device, according to some aspects of the present disclosure.

Like reference numbers and designations in the various drawings indicate like elements.

### DETAILED DESCRIPTION

Transistors may be used in memory cells and peripheral circuits of a memory device. For example, a one-transistor/one-capacitor (1T/1C) memory cell of a DRAM device has a capacitor and a transistor. A bit of data is stored in the capacitor, and the transistor serves as a switch to control discharging of the capacitor. Transistors are also commonly used in a sense amplifier, which is part of peripheral circuits of the DRAM device. The sense amplifier may be coupled to the memory cell through a bit line and may be configured to amplify a small voltage or current during a read operation of the memory cell.

To reduce size of memory devices and increase the memory cell density, chip makers use vertical transistors to replace planar transistors in memory cells of the memory devices. The planar transistors in the memory cells may have a horizontal structure with buried word lines in a substrate and bit lines above the substrate. A planar transistor may occupy a larger area in a memory cell because a source and a drain of the planar transistor are disposed laterally at different locations. In contrast, a vertical transistor usually has a semiconductor body extending vertically. A source and a drain of the vertical transistor may be disposed at two ends of the semiconductor body. Thus, replacing the planar transistor in the memory cells with the vertical transistors can reduce the occupied area of each memory cell and simplify layout of the interconnected structures of the memory cells, the word lines, and the bit lines.

The present disclosure provides techniques for a memory device to use vertical transistors in both memory cells and one or more peripheral circuits. For example, the memory device includes an array of memory cells and a peripheral circuit adjacent to the array of memory cells in a horizontal direction. Each of the array of memory cells includes a vertical transistor and a capacitor coupled to the vertical transistor in a vertical direction. The peripheral circuit includes at least one vertical transistor coupled to a memory cell in the array of memory cells through the vertical transistor of the memory cell.

The techniques described in this disclosure can be implemented to realize one or more of the following advantages. First, size of peripheral circuits of a memory device can be reduced. Second, memory cells and part of the peripheral circuits that use vertical transistors can be produced during the same fabrication process, which reduces the fabrication complexity and improves the yield. Third, metal wiring and routing of interconnect lines in the memory device are simplified, which can reduce the coupling capacitance of the memory device (for example, the coupling capacitance between bit lines and storage units). Fourth, mismatch of a sense amplifier can be reduced since the vertical transistor of the sense amplifier has a metal gate, which improves the sense amplifier's sense margin.

In the present disclosure, some implementations are described in the context of a DRAM device. However, it should be appreciated that such implementations are not so limited and are equally applicable to a memory device implemented using any other suitable technologies, such as phase-change memory (PCM), static random-access memory (SRAM), ferroelectric DRAM (FRAM), resistive memory, magnetic memory, spin transfer torque (STT) memory, or any combination thereof.

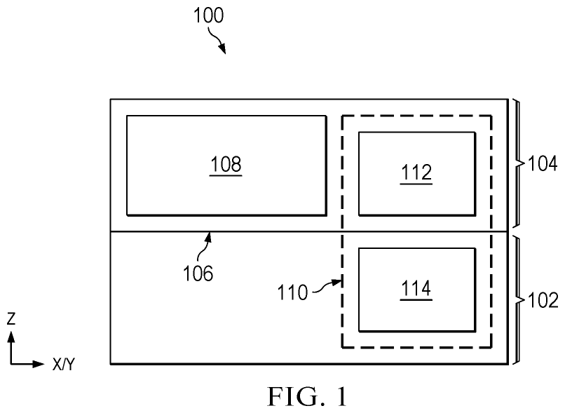

FIG. 1 illustrates a schematic view of a cross-section of a memory device 100, according to some aspects of the present disclosure. Memory device 100 represents an example of a bonded chip. Memory device 100 includes a semiconductor structure 102 and a semiconductor structure 104 bonded together. Semiconductor structure 104 including a memory cell array 108. The memory cell array 108 may also be referred to as an array of memory cells. The array of memory cells 108 (memory cell array) in semiconductor structure 104 may use vertical transistors as switch and selecting devices. In some implementations, the memory cell array 108 includes an array of DRAM cells.

Memory device 100 includes a peripheral circuit 110 of the memory cell array 108. The peripheral circuit 110, which may also be referred to as a control and sensing circuit, can include any suitable digital, analog, and/or mixed-signal circuits used for facilitating the operations of the memory cell array. For example, the peripheral circuit 110 can include one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors).

Peripheral circuit 110 includes a vertical circuit 112 and a planar circuit 114. Vertical circuit 112 is located within semiconductor structure 104 and includes one or more vertical transistors. Planar circuit 114 is located within semiconductor structure 102 and includes one or more planar transistors. Each of vertical circuit 112 and planar circuit 114 may also be referred to as a peripheral circuit or a portion (or a sub-circuit) of peripheral circuit 110. Both vertical circuit 112 and planar circuit 114 may use complementary metal-oxide-semiconductor (CMOS) technology, which can be implemented with logic processes (e.g., technology nodes of 90 nm, 65 nm, 60 nm, 45 nm, 32 nm, 28 nm, 22 nm, 20 nm, 16 nm, 14 nm, 10 nm, 7 nm, 5 nm, 3 nm, 2 nm, etc.), according to some implementations. In some implementations, semiconductor structure 102 is referred to as a CMOS wafer, and semiconductor structure 104 is referred to as an array wafer.

It is noted that x, y, and z axes are included in FIG. 1 to further illustrate the spatial relationship of various components in memory devices 100. A substrate of the memory device includes two lateral surfaces extending laterally in the x-y plane: a top surface on the front side of a wafer on which a component of the memory device can be formed, and a bottom surface on the backside opposite to the front side of the wafer. The z-axis is perpendicular to both the x and y axes. As used herein, whether one component (e.g., a layer or a device) is “on,” “above,” or “below” another component (e.g., a layer or a device) of the memory device is determined relative to the substrate of the memory device in the z-direction (the vertical direction perpendicular to the x-y plane, e.g., the thickness direction of the substrate) when the substrate is positioned in the lowest plane of the memory device in the z-direction. The same notion for describing the spatial relationships is applied throughout the present disclosure.

As shown in FIG. 1, memory device 100 further includes a bonding interface 106 between (in the vertical direction, e.g., the z-direction in FIG. 1) semiconductor structure 102 and semiconductor structure 104. The components of memory device 100 (such as semiconductor structure 102 and semiconductor structure 104) can be formed separately on different substrates and then jointed to form a bonded chip. Semiconductor structures 102 and 104 can be fabricated separately such that the thermal budget of fabricating one of semiconductor structures 102 and 104 does not limit the processes of fabricating another of semiconductor structures 102 and 104. In some implementations, semiconductor structure 102 and semiconductor structure 104 may be fabricated in parallel. Moreover, a large number of interconnects (e.g., bonding contacts) can be formed through bonding interface 106 to make direct, short-distance (e.g., micron-level) electrical connections between semiconductor structure 102 and semiconductor structure 104, as opposed to the long-distance (e.g., millimeter or centimeter-level) chip-to-chip data bus on the circuit board, such as printed circuit board (PCB), thereby eliminating chip interface delay and achieving high-speed I/O throughput with reduced power consumption. Data transfer between semiconductor structure 104 and semiconductor structure 102 (such as data transfer between memory cell array 108 and planar circuit 114 and data transfer between vertical circuit 112 and planar circuit 114) can be performed through the interconnects (e.g., bonding contacts) across bonding interface 106. By vertically integrating semiconductor structures 102 and 104, such as stacking both semiconductor structures 102 and 104 in the vertical direction, the chip size can be reduced, and the memory cell density can be increased.

In some implementations, semiconductor structures 102 and 104 are jointed through hybrid bonding, which is also known as “metal/dielectric hybrid bonding.” Hybrid bonding is a direct bonding technology (e.g., forming bonding between surfaces without using intermediate layers, such as solder or adhesives) and can obtain metal-metal (e.g., copper-to-copper) bonding and dielectric-dielectric (e.g., silicon oxide-to-silicon oxide) bonding simultaneously.

It should be appreciated that the relative positions of the stacked semiconductor structures 102 and 104 are not limited. In some implementations semiconductor structure 102 is located above semiconductor structure 104. In some implementations, semiconductor 102 is located adjacent to semiconductor structure 104 in the lateral direction (e.g., in the x-y plane).

In some implementations, semiconductor structure 104 includes multiple memory cell arrays 108. In some implementations, memory device 100 includes multiple peripheral circuits 110, and at least one of the multiple peripheral circuits 110 includes vertical circuit 112 located within semiconductor structure 104. In some implementations, all transistors in peripheral circuit 110 are vertical transistors and are located within vertical circuit 112, and planar circuit 114 may not include any transistor at all.

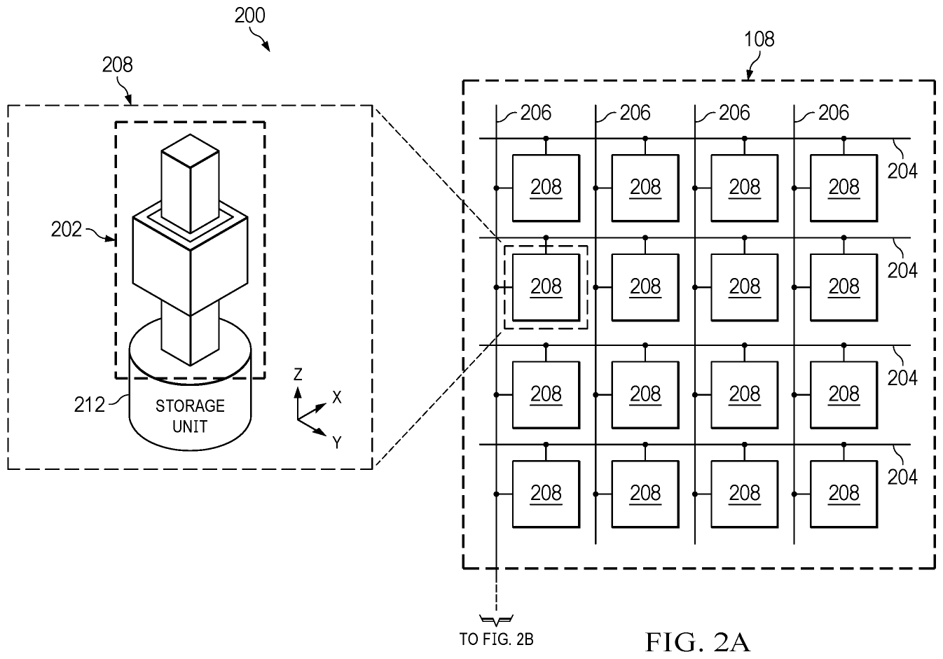

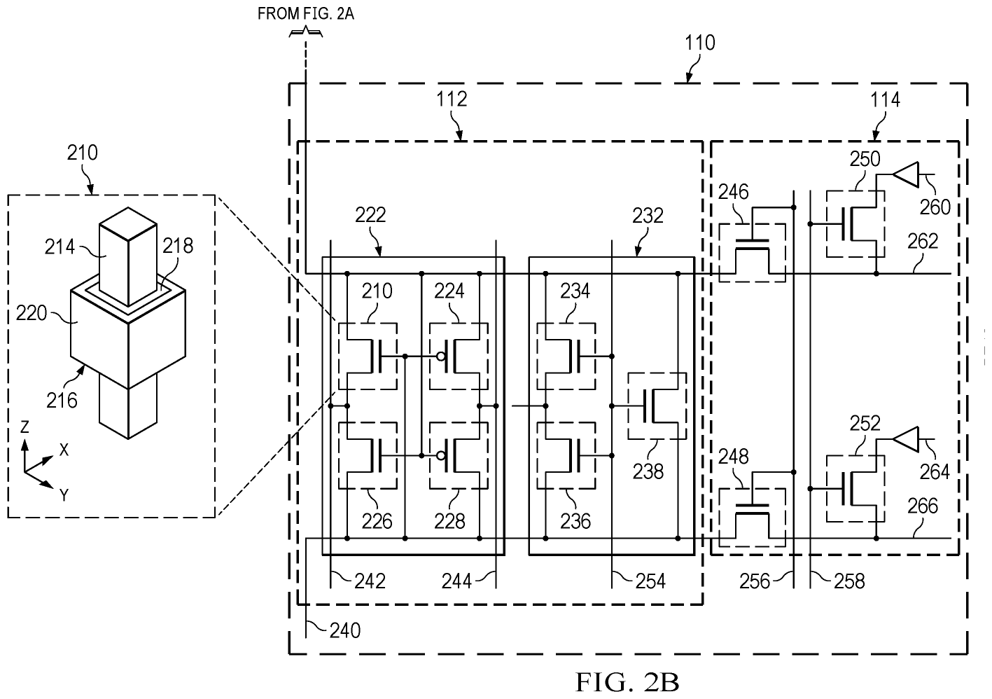

FIGS. 2A-2B illustrates a schematic diagram of a memory device 200 having vertical transistors, according to some aspects of the present disclosure. Memory device 200 includes memory cell array 108 and peripheral circuit 110 coupled together. Peripheral circuit 110 includes vertical circuit 112 and planar circuit 114. Memory device 200 may be an example of memory device 100 of FIG. 1. For instance, memory cell array 108 and vertical circuit 112 of memory device 200 are included in semiconductor structure 104, and planar circuit 114 of memory device 200 is included in semiconductor structure 102. Memory cell array 108 can be any suitable memory cell array in which each memory cell 208 includes a vertical transistor 202 and a storage unit 212 coupled together. In some implementations, memory cell 208 is a DRAM cell, and storage unit 212 is a capacitor for storing charge as the binary information stored by the DRAM cell.

As shown in FIG. 2A, memory cells 208 can be arranged in a two-dimensional (2D) array having rows and columns. Memory device 200 can include word lines 204 coupling peripheral circuit 110 and memory cell array 108 for controlling the switch of vertical transistors 202 in memory cells 208 located in a row, as well as bit lines 206 coupling peripheral circuit 110 and memory cell array 108 for sending data to and/or receiving data from memory cells 208 located in a column. That is, each word line 204 is coupled to a respective row of memory cells 208, and each bit line is coupled to a respective column of memory cells 208. In some implementations, each word line 204 is a vertical line and is coupled to a respective column of memory cells 208, and each bit line 206 is a horizontal line and is coupled to a respective row of memory cells 208.

In some implementations, vertical circuit 112 is a sense amplifier (SA), and planar circuit 114 is an I/O circuit. The vertical circuit 112 or SA 112 may be a differential SA. As shown in FIG. 2B, SA 112 includes a sensing circuit 222 and a voltage equalization circuit 232. Sensing circuit 222 and voltage equalization circuit 232 are coupled to bit line 206 and bit line 240. Sensing circuit 222 is also referred to as a latch circuit. Bit line 206 is located within memory cell array 108 and is configured to connect a column of memory cells 208 in memory cell array 108 to SA 112. Bit line 240 may be located within another memory cell array and serve as a reference for read operations performed on the column of memory cells 208 coupled to bit line 206. When storage unit 212 of memory cell 208 is discharging, SA 112 is configured to amplify a small voltage difference between bit line 206 and bit line 240 and output the amplified voltage to I/O driver 114. SA 112 may also be configured to recharge storage unit 212 to refresh memory cell 208 after the data stored in memory cell 208 is read.

In some implementations, sensing circuit 222 includes two N-type metal-oxide-semiconductor (NMOS) transistors 210 and 226 and two P-type metal-oxide-semiconductor (PMOS) transistors 224 and 228. NMOS transistors 210 and 226 are coupled to SA control line 242 (SAN). PMOS transistors 224 and 228 are coupled to SA control line 244 (SAP). In some implementations, sensing circuit 222 is constructed using CMOS technology. Voltage equalization circuit 232 includes transistors 234, 236, and 238 coupled to equalization line 254. In this example, transistors 210, 224, 226, 228, 234, 236, and 238 are vertical transistors.

FIG. 2B illustrates an example structure of vertical transistor 210. As shown in FIG. 2B, in some implementations, different from planar transistors in which the active regions are formed in the substrates, vertical transistor 210 includes a semiconductor body 214 extending vertically (in the z-direction) above a substrate where it is located (not shown in FIG. 2B). That is, semiconductor body 214 can extend above the top surface of the substrate to expose not only the top surface of semiconductor body 214, but also one or more side surfaces thereof. As shown in FIG. 2B, for example, semiconductor body 214 can have a cuboid shape to expose four sides thereof. It should be appreciated that semiconductor body 214 may have any suitable 3D shape, such as polyhedron shapes or a cylinder shape. That is, the cross-section of semiconductor body 214 in the plan view (e.g., in the x-y plane) can have a square shape, a rectangular shape (or a trapezoidal shape), a circular (or an oval shape), or any other suitable shapes. Consistent with the scope of the present disclosure, for semiconductor bodies that have a circular or oval shape of their cross-sections in the plan view, the semiconductor bodies may still be considered to having multiple sides, such that the gate structures are in contact with more than one side of the semiconductor bodies. As described below with respect to the fabrication process, semiconductor body 214 can be formed from the substrate (e.g., by etching or epitaxy) and thus, has the same semiconductor material (e.g., silicon crystalline silicon) as the substrate (e.g., a silicon substrate).

As shown in FIG. 2B, vertical transistor 210 can also include a gate structure 216 in contact with one or more sides of semiconductor body 214, i.e., in one or more planes of the side surface(s) of the active region. In other words, the active region of vertical transistor 210, i.e., semiconductor body 214, can be at least partially surrounded by gate structure 216. Gate structure 216 can include a gate dielectric 218 over one or more sides of semiconductor body 214, e.g., in contact with four side surfaces of semiconductor body 214 as shown in FIG. 2B. Gate structure 216 can also include a gate electrode 220 over and in contact with gate dielectric 218. Gate dielectric 218 can include any suitable dielectric materials, such as silicon oxide, silicon nitride, silicon oxynitride, or high-k dielectrics. For example, gate dielectric 218 may include silicon oxide, i.e., gate oxide. Gate electrode 220 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, gate electrode 220 may include doped polysilicon, i.e., a gate poly. In some implementations, gate electrode 220 includes multiple conductive layers, such as a W layer over a TiN layer.

Vertical transistor 210 can further include a pair of a source and a drain (S/D, dope regions, a.k.a., source electrode and drain electrode) formed at the two ends of semiconductor body 214 in the vertical direction (the z-direction), respectively. The source and drain can be doped with any suitable P-type dopants, such as boron (B) or Gallium (Ga), or any suitable N-type dopants, such as phosphorus (P) or arsenic (As). The source and drain can be separated by gate structure 216 in the vertical direction (the z-direction). In other words, gate structure 216 is formed vertically between the source and drain.

In some implementations, as shown in FIG. 2B, vertical transistor 210 is a multi-gate transistor. That is, gate structure 216 can be in contact with more than one side of semiconductor body 214 (e.g., four sides in FIG. 2B) to form more than one gate, such that more than one channel can be formed between the source and drain in operation. That is, different from the planar transistor that includes only a single planar gate (and resulting in a single planar channel), vertical transistor 210 shown in FIG. 2B can include multiple vertical gates on multiple sides of semiconductor body 214 due to the 3D structure of semiconductor body 214 and gate structure 216 that surrounds the multiple sides of semiconductor body 214. As a result, compared with planar transistors, vertical transistor 210 shown in FIG. 2B can have a larger gate control area to achieve better channel control with a smaller subthreshold swing. During the off state, since the channel is fully depleted, the leakage current (10 f) of vertical transistor 210 can be significantly reduced a well. As described below in detail, the multi-gate vertical transistors can include double-gate vertical transistors (e.g., dual-side gate vertical transistors), tri-gate vertical transistors (e.g., tri-side gate vertical transistors), and gate-all-around (GAA) vertical transistors.

Although vertical transistor 210 is shown as a multi-gate transistor in FIG. 2B, the vertical transistors disclosed herein may also include single-gate transistors as described below in detail. That is, gate structure 216 may be in contact with a single side of semiconductor body 214. for example, for the purpose of increasing the transistor and memory cell density. It should be appreciated that although gate dielectric 218 is shown as being separate (i.e., a separate structure) from other gate dielectrics of adjacent vertical transistors (not shown), gate dielectric 218 may be part of a continuous dielectric layer having multiple gate dielectrics of vertical transistors.

In planar transistors and some lateral multiple-gate transistors (e.g., fin field-effect transistor (FinFET)), the active regions, such as semiconductor bodies (e.g., Fins), extend laterally (in the x-y plane), and the source and the drain are disposed at different locations in the same lateral plane (the x-y plane). In contrast, in vertical transistor 210, semiconductor body 214 extends vertically (in the z-direction), and the source and the drain are disposed in the different lateral planes, according to some implementations. In some implementations, the source and the drain are formed at two ends of semiconductor body 214 in the vertical direction (the z-direction), respectively, thereby being overlapped in the plan view. As a result, the area (in the x-y plane) occupied by vertical transistor 210 can be reduced compared with planar transistor and lateral multiple-gate transistors. Also, the metal wiring coupled to vertical transistor 210 can be simplified because vertical transistor 210, memory cell 208 and bit line 206 are located within the same semiconductor structure (such as semiconductor structure 104 of FIG. 1).

Transistor 202 of each memory cell 208 is also a vertical transistor and may have a structure similar to transistor 210. In some implementations, a gate of transistor 202 is coupled to word line 204, one of a source and a drain of transistor 202 is coupled to bit line 206, another of the source and the drain of transistor 202 is coupled to one electrode of storage unit 212, and another electrode of storage unit 212 is coupled to the ground. In other words, transistor 202 of memory cell 208 is coupled to transistor 210 through bit line 206.

Planar circuit 114 includes transistors 246 and 248 coupled to column-selection line (CSL) 256 and transistors 250 and 252 coupled to write enable (WE) line 258. The transistors 246, 248, 250, and 252 are planar transistors. Planar circuit 114 further includes input ports 260 and 264 and output ports 262 and 266. In some implementations, planar circuit 114 may include any other portion of sensing circuit 222 or the SA circuit of FIG. 2B that is not located within vertical circuit 112.

Although FIGS. 2A-2B illustrate an exemplary memory device having vertical transistors, this example is not intended to be construed in a limiting sense. Other implementations, alterations, and permutations of the described implementation that are apparent to those skilled in the art are also applicable without departing from the spirit and scope of the present disclosure. For example, a sense circuit or a voltage equalization circuit with any suitable number of transistors may be used in the peripheral circuit 110.

In some implementations, a part of the SA circuit of FIG. 2B is located within vertical circuit 112, and the remaining part of the SA circuit is located within planar circuit 114. For example, sense circuit 222 is implemented using vertical transistors and is located within vertical circuit 112, and voltage equalization circuit 232 is implemented using planar transistors and is located within planar circuit 114. In some implementations, any part of peripheral circuit 110 (such as transistor 246 of the I/O circuit) may be implemented using vertical transistors and located within vertical circuit 112. In some implementations, the entire peripheral circuit 110 may be implemented using vertical transistor and integrated into semiconductor structure 104. In some implementations, peripheral circuit 110 includes a word line driver (not shown in FIGS. 2A-2B). Vertical circuit 112 includes a first portion of the word line driver, and the first portion of the word line driver includes a vertical transistor. Planar circuit 114 includes a second portion of the word line driver, and the second portion of the word line driver includes a planar transistor.

In some implementations, vertical circuit 112 is a portion of sensing circuit 222. For example, vertical circuit 112 may include transistors 210 and 224. Transistors 226 and 228 of sensing circuit 222 are located outside of vertical circuit 112.

To determine which part of peripheral circuit 110 can be implemented using vertical transistors and integrated into semiconductor structure 104, one or more of the following factors may be considered. The first factor is whether vertical transistors can satisfy performance requirements of peripheral circuit 110. For example, the performance requirements may include channel length, driven current, and Vds (maximum voltage between drain and source). The second factor is a size limit for the semiconductor structure 104. The third factor is a density requirement for the memory cells in the semiconductor structure 104. For example, if the size of the semiconductor structure 104 is fixed, adding a portion of or the entire peripheral circuit into semiconductor structure 104 may occupy a space that could have been used for memory cells, which may affect the memory cell density.

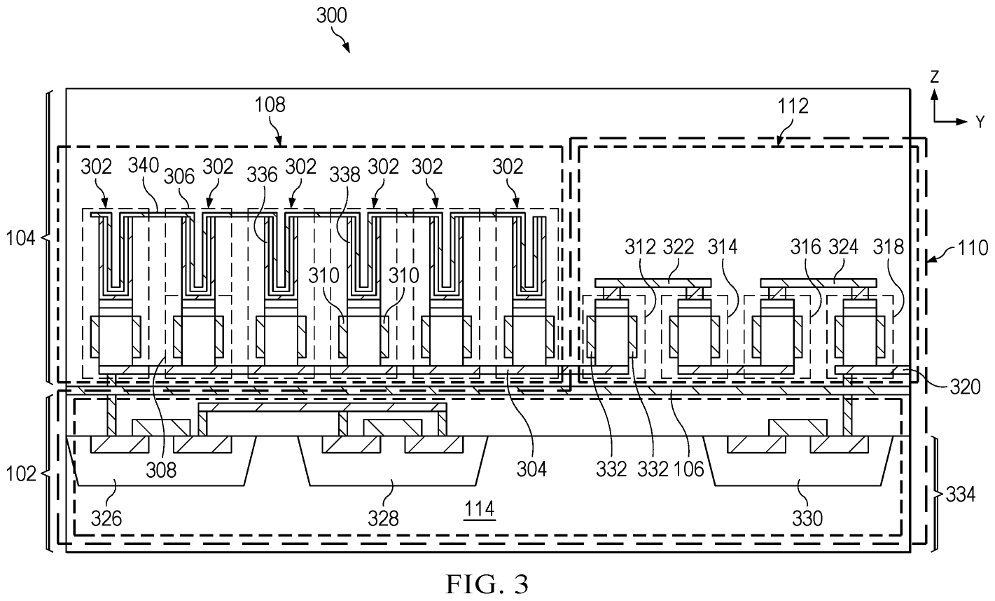

FIG. 3 illustrates a side view of a cross-section of a memory device 300 including vertical transistors, according to some aspects of the present disclosure. It should be appreciated that FIG. 3 is for illustrative purposes only and may not necessarily reflect the actual device structure (e.g., interconnections) in practice. As one example of memory device 100 in FIG. 1, memory device 300 is a bonded chip including semiconductor structure 102 and semiconductor structure 104 stacked over semiconductor structure 102. Semiconductor structures 102 and 104 are jointed at bonding interface 106 therebetween, according to some implementations. Memory device 300 includes memory cell array 108 and peripheral circuit 110 of memory cell array 108. Memory cell array 108 is located within semiconductor structure 104. Peripheral circuit 110 includes vertical circuit 112 located within semiconductor structure 104 and planar circuit 114 located within semiconductor structure 102.

Memory cell array 108 includes an array of memory cells and multiple bit lines. The cross-section of memory device 300 in FIG. 3 may be made along the bit line direction (the y-direction). One of the multiple bit lines (bit line 304) extends laterally in the y-direction and is coupled to a column of memory cells 302 of the array of memory cells. Each memory cell 302 includes a vertical transistor 308 (such as vertical transistor 202 of FIG. 2A) and a capacitor 306 (such as capacitor 212 of FIG. 2A). Vertical transistor 308 includes a semiconductor body extending vertically (in the z-direction) and a source and a drain disposed at two ends (the upper end and lower end) of the semiconductor body. Vertical transistor 308 may have one end (one of vertical transistor 308's source or drain) coupled to bit line 304 and another end (another of vertical transistor 308's source or drain) coupled to capacitor 306. In some implementations, vertical transistor 308 has double gates 310.

As shown in FIG. 3, in some implementations, each capacitor 306 includes an electrode 336 above and in contact with the source or the drain of vertical transistor 308. Capacitor 306 also includes a capacitor dielectric 338 above and in contact with electrode 336, and another electrode 340 above and in contact with capacitor dielectric 338. That is, capacitor dielectric 338 is sandwiched between electrodes 336 and 340. In some implementations, each electrode 336 is coupled to a respective vertical transistor 308 in the same memory cell 302, while all electrodes 340 are parts of a common conductive structure coupled to the ground. The structure and configuration of capacitor 306 are not limited to the example in FIG. 3 and may include any suitable structure and configuration, such as a planar capacitor, a stack capacitor, a multi-fins capacitor, a cylinder capacitor, a trench capacitor, or a substrate-plate capacitor. In some implementations, memory cells 302 may have any suitable structures and configurations such 1T, 1T1C, or 1TnC. That is, the quantity of capacitors connected to the vertical transistor of memory cell 302 can be 0, 1, or n (n being an integer). In some implementations, capacitor dielectric 338 is made of dielectric materials, such as silicon oxide, silicon nitride, or high-k dielectrics including, but not limited to, Al2O3, HfO2, Ta2O5, ZrO2, TiO2, or any combination thereof. It should be appreciated that in some examples, capacitor 306 may be a ferroelectric capacitor used in a FRAM cell, and capacitor dielectric 338 may be replaced by a ferroelectric layer having ferroelectric materials, such as lead zirconate titanate (PZT) or strontium bismuth tantalate (SBT). In some implementations, electrodes 336 and 340 are made of conductive materials including, but not limited to W, Co, Cu, Al, TiN. TaN, polysilicon, silicides, or any combination thereof.

Vertical circuit 112 includes vertical transistors 312, 314, 316, and 318 of peripheral circuit 110. In some implementations, vertical transistors 312, 314, 316, and 318 also have double gates (such as gates 332 of vertical transistor 318). Vertical circuit 112 may be coupled to bit lines from different memory cell arrays. As shown in FIG. 3, vertical circuit 112 is coupled to bit line 304 through vertical transistor 312 and coupled to bit line 320 through vertical transistor 318. Bit line 320 is from another memory cell array (not shown in FIG. 3), which may also be located within semiconductor structure 104. Each of vertical transistors 312, 314, 316, and 318 may include a semiconductor body extending vertically (in the z-direction) and a source and a drain disposed at two ends (the upper end and lower end) of the semiconductor body. Each of vertical transistors 312, 314, 316, and 318 may be coupled to a bit line (such as bit line 304 or bit line 320) through one of its source or drain and coupled to some other interconnect lines (such as line 322 or line 324) through another of its source or drain. Vertical transistors 312, 314, 316, and 318 may be implemented using CMOS technology. For example, line 322 is an SAN line of an SA circuit (such as SAN 242 of FIG. 2B) and vertical transistors 312 and 314 are NMOS transistors (such as transistors 210 and 226 of FIG. 2B). Line 324 may be an SAP line of the SA circuit (such as SAP 244 of FIG. 2B) and vertical transistors 316 and 318 are PMOS transistors (such as transistors 224 and 228 of FIG. 2B).

In some implementations, vertical transistors (such as vertical transistors 308, 312, 314, 316, and 318) in semiconductor structure 104 may have different dimensions based on their specific performance requirements. For instance, the semiconductor bodies and the gate structures of the vertical transistors may have different sizes (different length, width, or height). In another example, the gate dielectric layers of these vertical transistors may have different thicknesses.

The vertical transistors in vertical circuit 112 are not limited to the example in FIG. 3 and may include any suitable number of vertical transistors. In some implementations, vertical circuit 112 may include less than four vertical transistors (such as one) or more than four vertical transistors. The vertical transistors in vertical circuit 112 may belong to a latch circuit, a sense amplifier, a page buffer, a decoder (such as a row decode and a column decoder), a driver (such as a word line driver and a bit line driver), an I/O circuit, a charge pump, a voltage source or generator, or a current or voltage reference of peripheral circuit 110. In addition, the vertical transistors in vertical circuit 112 may belong to any combination of the above circuits. Some factors (such as the performance requirements of a sub-circuit of peripheral circuit 110, the size limit for semiconductor structure 104, and the density requirement for the memory cells in semiconductor structure 104) may be considered to determine which part of peripheral circuit 110 can be implemented using vertical transistors and integrated into vertical circuit 112, as previously described regarding FIGS. 2A-2B.

As shown in FIG. 3, semiconductor structure 102 can include a substrate 334, which may be made of silicon (e.g., single crystalline silicon, c-Si), silicon germanium (SiGe), gallium arsenide (GaAs), germanium (Ge), silicon-on-insulator (SOI), or any other suitable materials. Planar circuit 114 includes planar transistors 326, 328, and 330 of peripheral circuit 110, which are located on substrate 334.

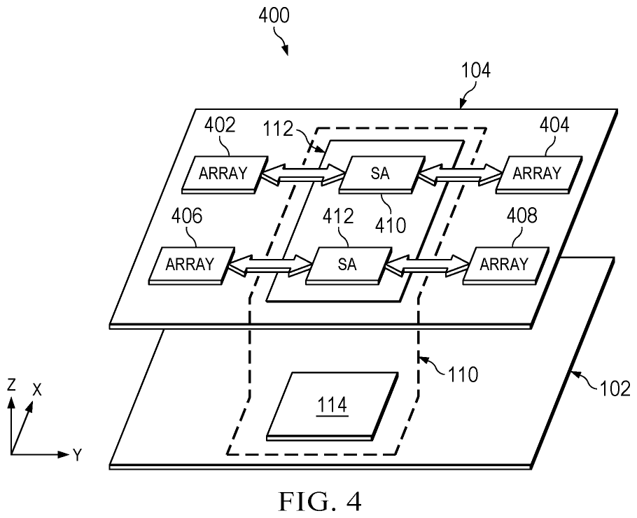

FIG. 4 illustrates a memory device 400 having multiple memory cell arrays, according to some aspects of the present disclosure. Memory device 400 is a bonded chip including semiconductor structure 102 and semiconductor structure 104. Semiconductor structure 104 is stacked over semiconductor structure 102. Semiconductor structures 102 and 104 are jointed at a bonding interface therebetween (not shown in FIG. 4), according to some implementations. Memory device 400 includes memory cell arrays 402, 404, 406, and 408 and peripheral circuit 110 of these memory cell arrays. Memory cell arrays 402, 404, 406, and 408 are located within semiconductor structure 104. Peripheral circuit 110 includes vertical circuit 112 located within semiconductor structure 104 and planar circuit 114 located within semiconductor structure 102. Vertical circuit 112 includes one or more vertical transistors, and planar circuit 114 includes one or more planar transistors. Vertical circuit 112 includes circuit 410 and circuit 412. Each of circuits 410 and 412 may also be referred to as a peripheral circuit.

As shown in FIG. 4, circuit 410 is coupled to both memory cell arrays 402 and 404. Memory cell array 402, circuit 410, and memory cell array 404 are located along the y direction. Circuit 410 is disposed between memory cell arrays 402 and 404. Circuit 412 is coupled to both memory cell arrays 406 and 408. Memory cell array 406, circuit 412, and memory cell array 408 also are located along the y direction. Circuit 412 is disposed between memory cell arrays 406 and 408. Vertical transistors of memory cell arrays 402, 404, 406, and 408 and vertical circuit 112 have their semiconductor bodies extending vertically in the z direction.

In some implementations, circuit 410 is coupled to bit lines of memory cell arrays 402 through a set of vertical transistors of circuit 410. Circuit 410 is further coupled to bit lines of memory cell arrays 404 through another set of vertical transistors of circuit 410.

In some implementations, circuit 410 is coupled to word lines of memory cell arrays 402 through a set of vertical transistors of circuit 410. Circuit 410 is further coupled to word lines of memory cell arrays 404 through another set of vertical transistors of circuit 410.

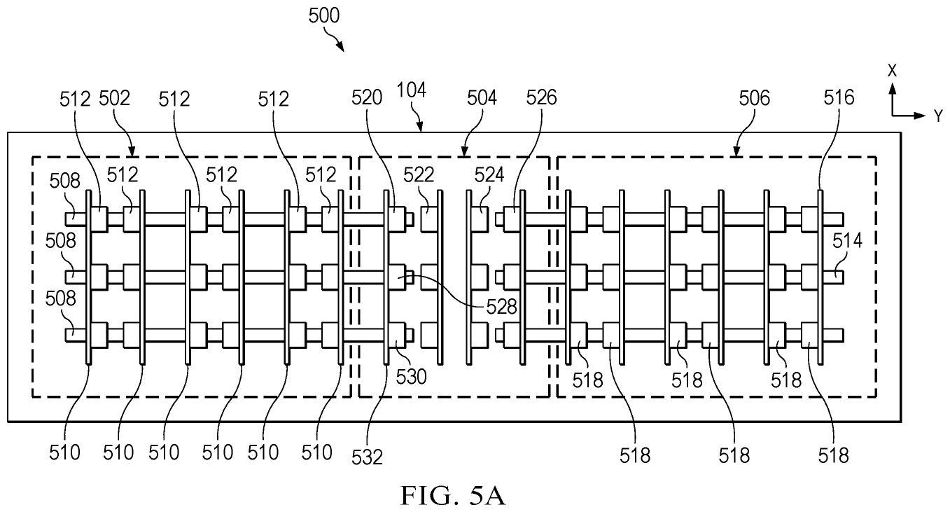

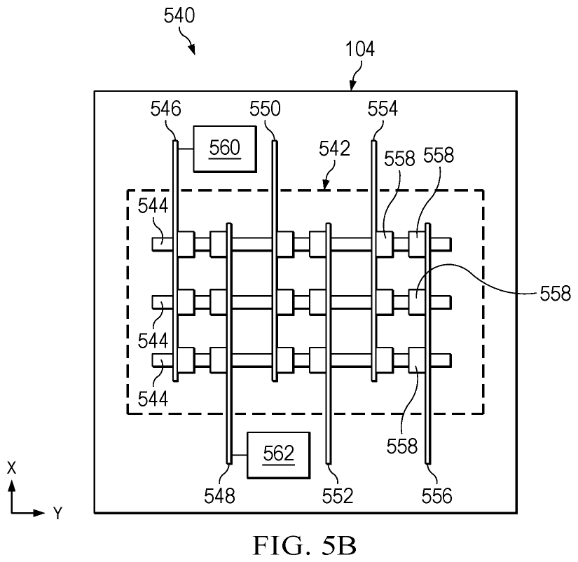

FIG. 5A illustrates a plan view of a memory device 500 having two memory cell arrays, according to some aspects of the present disclosure. Memory device 500 is a bonded chip including semiconductor structure 104 and another semiconductor structure. Semiconductor structure 104 is stacked over the other semiconductor structure. Semiconductor structure 104 and the other semiconductor structure are jointed at a bonding interface therebetween, according to some implementations. The other semiconductor and the bonding interface are not shown in FIG. 5A. Semiconductor structure 104 includes memory cell array 502, circuit 504, and memory cell array 506 located along the y direction. Memory cell array 502, circuit 504, and memory cell array 506 all include vertical transistors. In some implementations, circuit 504 is an example of vertical circuit 112 of FIG. 1.

Memory cell array 502 includes multiple bit lines 508 extending in the y direction and multiple word lines 510 extending in the x direction. Memory cell array 502 further includes memory cells formed at intersections of bit lines 508 and word lines 510. Each memory cell of memory cell array 502 includes a respective vertical transistor 512. Memory cell array 506 includes multiple bit lines 514 extending in the y direction and multiple word lines 516 extending in the x direction. Memory cell array 506 further includes memory cells formed at intersections of bit lines 514 and word lines 516. Each memory cell of memory cell array 506 includes a respective vertical transistor 518. Circuit 504 also includes an array of vertical transistors. Each vertical transistor in memory cell array 502, circuit 504, and memory cell array 506 has a semiconductor body extending vertically (in a direction perpendicular to the x-y plane). As shown in FIG. 5A, these vertical transistors are single-gate transistors that have gate electrodes in contact with one side of their semiconductor bodies and serving as part of a corresponding word line.

Each row of vertical transistors of circuit 504 is coupled to a respective bit line 508 in memory cell array 502 and a respective bit line 514 in memory cell array 506. In some implementations, each row of vertical transistors of circuit 504 is a portion of a sensing amplifier (such as the latch circuit 222 of FIG. 2B). For example, vertical transistors 520, 522, 524, and 526 are examples of vertical transistors 210, 226, 224, and 228 of FIG. 2B, respectively. As shown in FIG. 5A, vertical transistor 520 is coupled to bit line 508, and vertical transistor 526 is coupled to bit line 514. In some implementations, vertical transistors 520, 522, 524, and 526 are constructed using CMOS technology.

It should be appreciated that FIG. 5A is for illustrative purposes only, and the actual device structure (e.g., interconnections) in practice is not limited to the structure shown in FIG. 5A. Interconnections between vertical transistors of circuit 504 may depend on actual requirements and configurations of circuit 504. In some implementations, each column of vertical transistors of circuit 504 have their gate electrodes coupled to the same connection line. For example, as shown in FIG. 5A, the gate electrodes of vertical transistors 520, 528, and 530 are part of connection line 532. In some implementations, connection line 532 may be separated by gaps between two adjacent vertical transistors if gate electrodes of the two adjacent vertical transistors are not to be coupled together.

FIG. 5B illustrates a plan view of a memory device 550 having at least one word line driver device, according to some aspects of the present disclosure. Memory device 540 is a bonded chip including semiconductor structure 104 and another semiconductor structure. Semiconductor structure 104 is stacked over the other semiconductor structure. Semiconductor structure 104 and the other semiconductor structure are jointed at a bonding interface therebetween, according to some implementations. The other semiconductor and the bonding interface are not shown in FIG. 5B. Semiconductor structure 104 includes memory cell array 542 and a word line driver device 560 located in the x-y plane. Memory cell array 542 includes multiple bit lines 544 extending in the y direction and multiple word lines 546, 548, 550, 552, 554, and 556 extending in the x direction. Memory cell array 542 further includes memory cells formed at intersections of bit lines 544 and word lines 546-556. Each memory cell of memory cell array 542 includes a respective vertical transistor 558.

Both memory cell array 542 and word line driver device 560 include vertical transistors. In some implementations, as shown in FIG. 5B, word line driver device 560 is adjacent to memory cell array 542 along the y direction. At least a terminal of word line driver device 560 is electrically connected to a word line (e.g., word line 546) of memory cell array 542. The terminal of word line driver device 560 may be a source or a drain of a vertical transistor of word line driver device 560. In some implementations, the terminal of word line driver device 560 may be directly connected to a word line of memory cell array 542. In some implementations, the terminal of word line driver device 560 may be indirectly connected to a word line of memory cell array 542 through another device (e.g., a conductive wire such as metal, a jump wire, or a switch device).

In some implementations, memory cell array 542 is coupled to more than one word line driver devices. The word line driver devices coupled to adjacent word lines may be located at opposite sides of memory cell array 542. For example, as shown in FIG. 5B, word line driver device 560 is coupled to word line 546 and is located on top of memory cell array 542. Word line driver device 562 is coupled to word line 548 (which is adjacent to word line 546) and is located on the bottom of memory cell array 542, which is opposite to word line driver device 560. In some implementations, each word line of memory cell array 542 including word lines 550, 552, 554, and 556 are coupled to a word line driver device located similar to word line driver devices 560 and 562.

Components of a memory device (such as the CMOS wafer or semiconductor structure 102 of FIG. 1 and the array wafer or semiconductor structure 104 of FIG. 1) can be formed separately on different substrates and then jointed to form a bonded chip. The array wafer and the CMOS wafer can be fabricated separately such that the thermal budget of fabricating one of them does not limit the processes of fabricating another. In some implementations, the array wafer and the CMOS wafer may be fabricated in parallel.

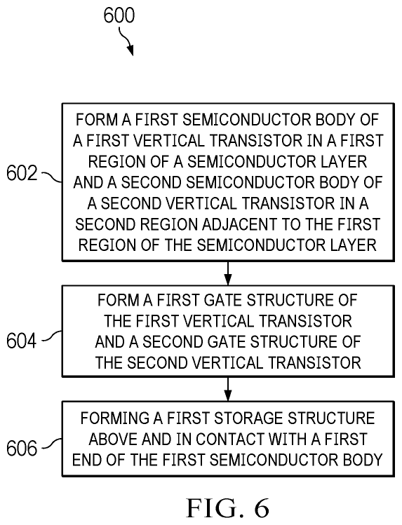

FIG. 6 illustrates a flowchart of a method 600 for forming an array wafer of a memory device, according to some aspects of the present disclosure. At operation 602, a first semiconductor body of a first vertical transistor in a first region of a semiconductor layer (also referred to as an array wafer or a semiconductor structure) and a second semiconductor body of a second vertical transistor in a second region adjacent to the first region of the semiconductor layer are formed. In some implementations, the first region is referred to as an array region or a core array region, and the second region is referred to as a circuit region. The first semiconductor body and the second semiconductor body are formed on a first side of the semiconductor layer. In some implementations, the second region is adjacent to the first region in a lateral direction (such as the y direction). In some implementations, the first semiconductor body and the second semiconductor body extend vertically in a direction perpendicular to the lateral direction (such as the z direction). The semiconductor layer can be a Silicon-on-Insulator (SOI) substrate. In some implementations, to form the first semiconductor body and the second semiconductor body, the semiconductor layer is etched in two lateral directions, such that the two opposite sides of each semiconductor body are exposed.

In some implementations, operation 602 further includes forming a third semiconductor body of a third vertical transistor. The third semiconductor body of the third vertical transistor may be located in the second region.

In some implementations, operation 602 further includes doping the first region of the semiconductor layer with a P-type dopant to form the first semiconductor body of the first vertical transistor. Operation 602 may further include doping a part of the second region of the semiconductor layer with the P-type dopant to form the second semiconductor body semiconductor of the second vertical transistor. Operation 602 may further include doping another part of the second region of the semiconductor layer with an N-type dopant to form the third semiconductor body of the third vertical transistor.

In some implementations, operation 602 further includes forming a fourth semiconductor body of a fourth vertical transistor in a third region of the semiconductor layer. The third region is adjacent to the second region in the lateral direction (such as the y direction). The second region is located between the first region and the third region.

At operation 604, a first gate structure of the first vertical transistor and a second gate structure of the second vertical transistor are formed. The first gate structure is in contact with at least one side of the first semiconductor body, and the second gate structure is in contact with at least one side of the second semiconductor body. The first gate structure may include a first conductive layer and a first gate dielectric layer disposed between the first conductive layer and the first semiconductor body. The second gate structure may include a second conductive layer and a second gate dielectric layer disposed between the second conductive layer and the second semiconductor body. The size of the second gate structure (such as length, width, thickness of the dielectric layer or the conductive layer) may be different from the first gate structure. In some implementations, operation 604 further includes a metal gate doping process to adjust work-function of either the first gate structure or the second gate structure or both.

In some implementations, operation 604 further includes forming a third gate structure in contact with at least one side of the third semiconductor body. Operation 604 may further include forming a fourth gate structure in contact with at least one side of the fourth semiconductor body.

At operation 606, a first storage structure is formed. The first storage structure is located above and in contact with a first end of the first semiconductor body. Operation 606 may further include forming a second storage structure above and in contact with a first end of the fourth semiconductor body.

In some implementations, method 600 further includes removing a portion of the semiconductor layer from a second side to expose a second end of the first semiconductor body opposite to the first end of the first semiconductor body, a first end of the second semiconductor body, and a first end of the third semiconductor body. Method 600 may further include forming a first bit line in contact with the second end of the first semiconductor body, a second end of the second semiconductor body, and a second end of the third semiconductor body. The first end of the second semiconductor body may be coupled to the fourth vertical transistor. The first end of the third semiconductor body may be coupled to a fifth vertical transistor.

In some implementations, method 600 further includes removing a portion of the semiconductor layer from a second side to expose a second end of the fourth semiconductor body opposite to the first end of the fourth semiconductor body. Method 600 may further include forming a second bit line in contact with the second end of the fourth semiconductor body.

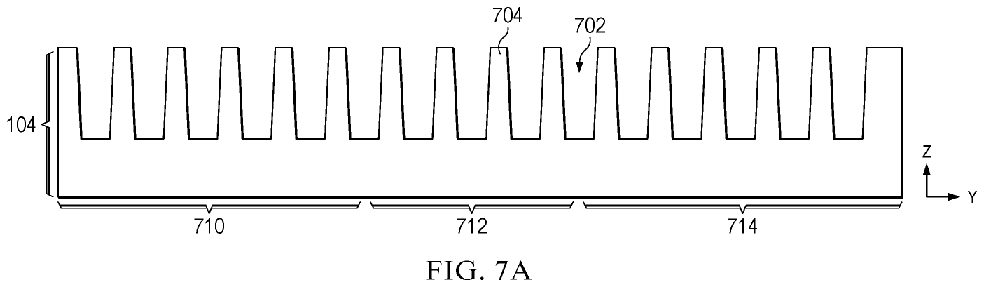

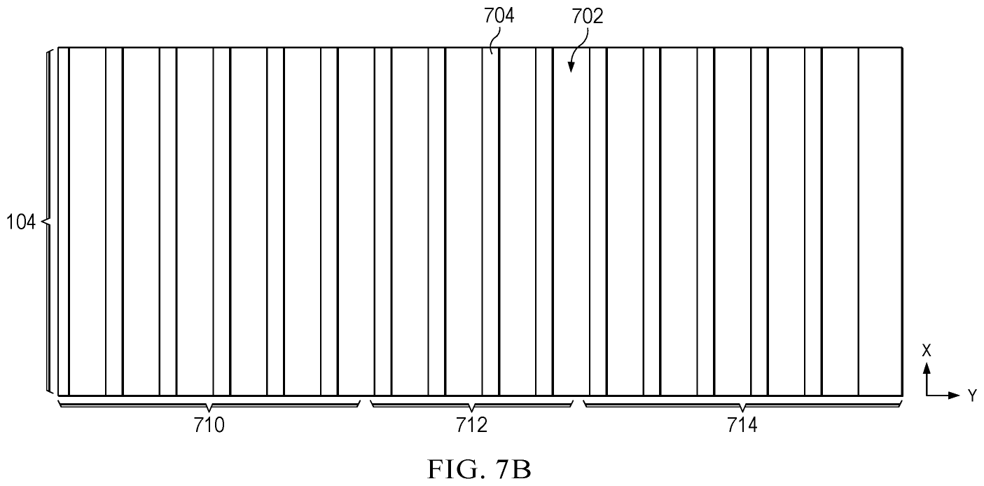

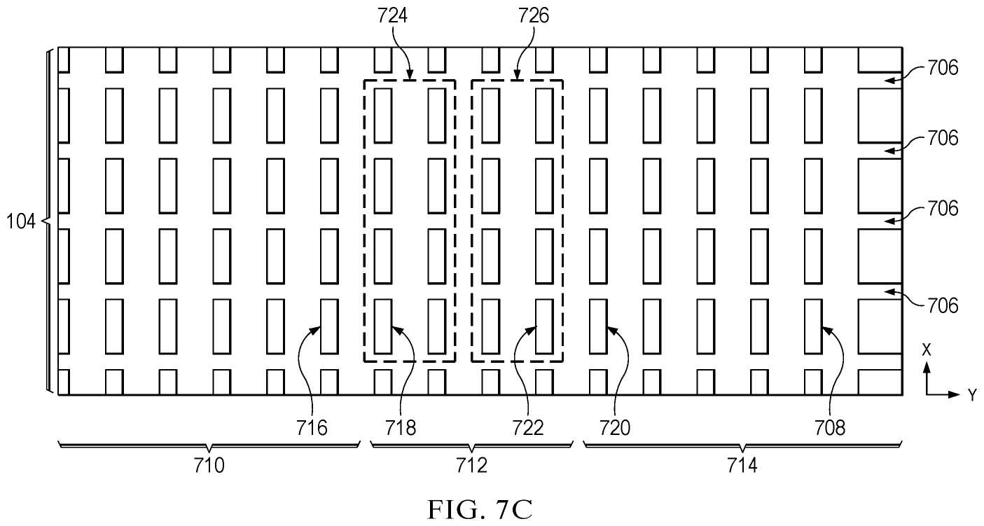

FIGS. 7A-7C illustrate examples of semiconductor layer 104 with trenches, according to some aspects of the present disclosure. FIG. 7A illustrates a side view of a cross-section of semiconductor layer 104 with trenches, according to some aspects of the present disclosure. FIGS. 7B and 7C each illustrates a plan view of semiconductor layer 104 with trenches, according to some aspects of the present disclosure. As illustrated in FIGS. 7A and 7B, a plurality of parallel trenches 702 are formed in the x direction to form a plurality of parallel semiconductor walls 704 of semiconductor layer 104 in the x direction. In some implementations, a lithography process is performed to pattern trenches 702 and semiconductor walls 704 using an etch mask (e.g., a photoresist mask and/or a hard mask), and one or more dry etching and/or wet etching processes, such as reactive-ion etching (RIE), are performed to etch trenches 702 in semiconductor layer 104. Thus, semiconductor walls 704 extending vertically (in the z direction) in semiconductor layer 104 can be formed. As illustrated in FIG. 7C, a plurality of parallel trenches 706 are formed in the y direction to form an array of semiconductor bodies 708 each extending vertically (in the z direction) in semiconductor layer 104.

In some implementations, trenches 702 and 706 may be formed in two consecutive processes. Alternatively, in some implementations, trenches 702 and 706 may be formed in the same process. For example, the same lithography process may be used to pattern trenches 702 and 706, followed by the same etching process. In some implementations, trenches 706 in the y direction may be formed prior to the formation of trenches 702 in the x direction. Nevertheless, after the formation of trenches 702 and 706, an array of semiconductor bodies 708 can be formed, and all four sides of each semiconductor body 708 may be exposed by trenches 702 and 706. In other words, semiconductor body 708 can be surrounded by trenches 702 and 706.

As illustrated in FIGS. 7A-7C, semiconductor layer 104 includes region 710 and region 712. Region 710 is an example of the first region of the semiconductor layer at operation 602 of method 600. Region 712 is an example of the second region of the semiconductor layer at operation 602. Semiconductor body 716 in region 710 is an example of the first semiconductor body at operation 602. Semiconductor body 718 in region 712 is an example of the second semiconductor body at operation 602. In some implementations, semiconductor bodies in region 710 belong to vertical memory cells in a memory cell array (such as memory cell array 108 in FIG. 1 or memory cell array 402 in FIG. 4). In some implementations, semiconductor bodies in region 712 belong to vertical transistors in a peripheral circuit (such as vertical circuit 112 in FIG. 1, circuit 410 in FIG. 4, or circuit 504 in FIG. 5A).

In some implementations, multiple semiconductor bodies in region 712 are formed. The multiple semiconductor bodies include semiconductor body 718 and semiconductor body 722. Semiconductor body 722 in region 712 is an example of the third semiconductor body in operation 602.

In some implementations, the semiconductor layer 104 is doped to obtain doped semiconductor bodies for the vertical transistors that are to be produced. The doping of the semiconductor bodies of the semiconductor layer 104 may occur prior to etching trenches 702 and 706. The dopant used for doping the semiconductor layer 104 may depend on types of the vertical transistors that are to be produced. In some implementations, the vertical transistors in the semiconductor layer 104 are of the same type. In this case, the same type of dopant may be applied to the entire semiconductor layer 104. For example, doping the semiconductor layer 104 with a P-type dopant can create P-type semiconductor bodies for NMOS transistors. In another example, doping the semiconductor layer 104 with an N-type dopant can create N-type semiconductor bodies for PMOS transistors.

In some implementations, the vertical transistors in the semiconductor layer 104 are of different types. For examples, semiconductor bodies in region 710 may belong to NMOS transistors (such as transistor 202 of FIG. 2A), semiconductor bodies in region 724 may belong to NMOS transistors (such as transistors 210 and 226 of FIG. 2B), and semiconductor bodies in region 726 may belong to PMOS transistors (such as transistors 224 and 228 of FIG. 2B). In this case, different regions of semiconductor layer 104 may be doped with different dopants. For example, regions 710 and 724 can be doped with a P-type dopant, and region 726 can be doped with a N-type dopant.

As illustrated in FIG. 7C, semiconductor layer 104 may include region 714. Regions 710, 712, and 714 are located in the semiconductor layer 104 in the y direction. Region 712 is located between regions 710 and 714. Region 714 is an example of the third region in method 600. Semiconductor body 720 in region 714 is an example of the fourth semiconductor body in the third region in method 600. In some implementations, semiconductor bodies in region 714 belong to vertical memory cells in another memory cell array (such as memory cell array 404 in FIG. 4 or memory cell array 506 in FIG. 5A).

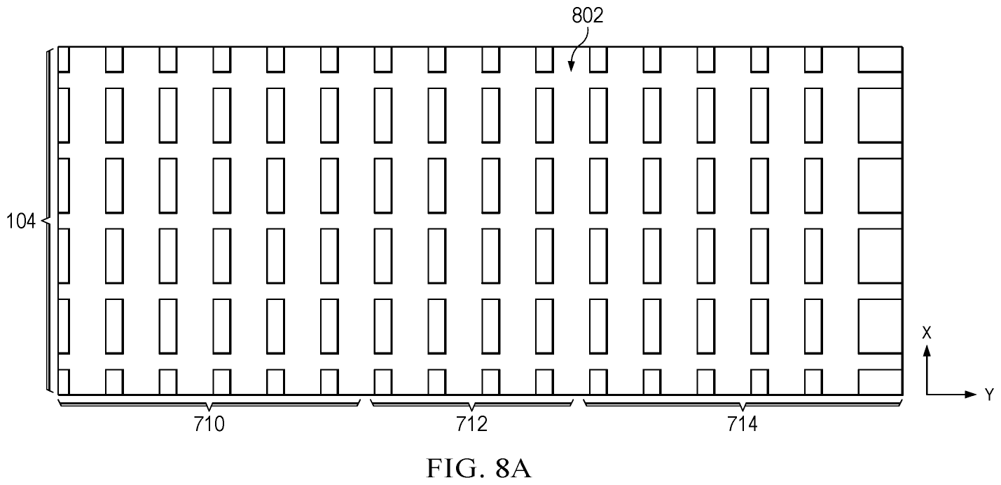

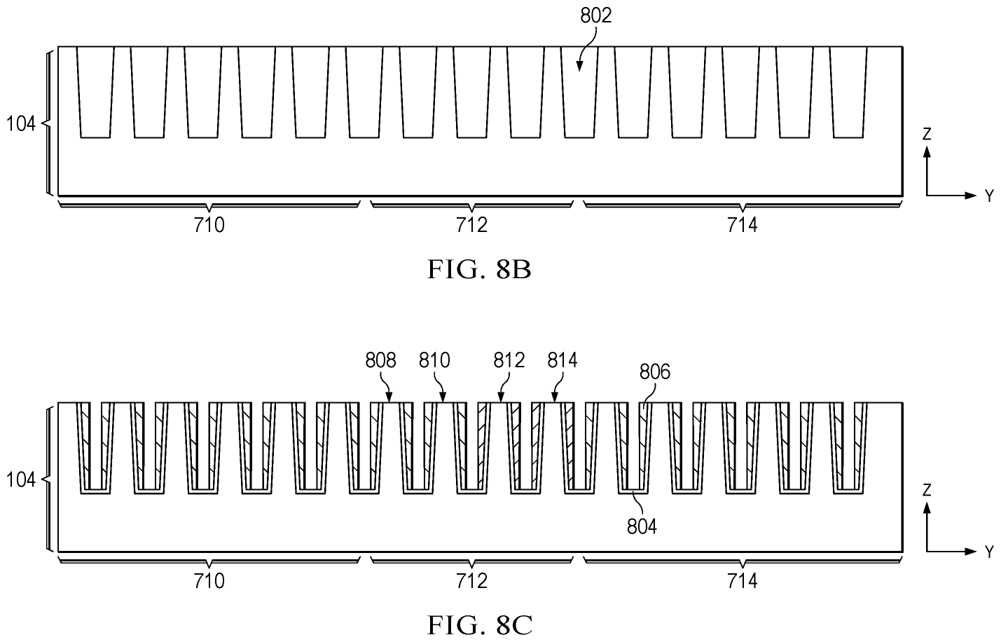

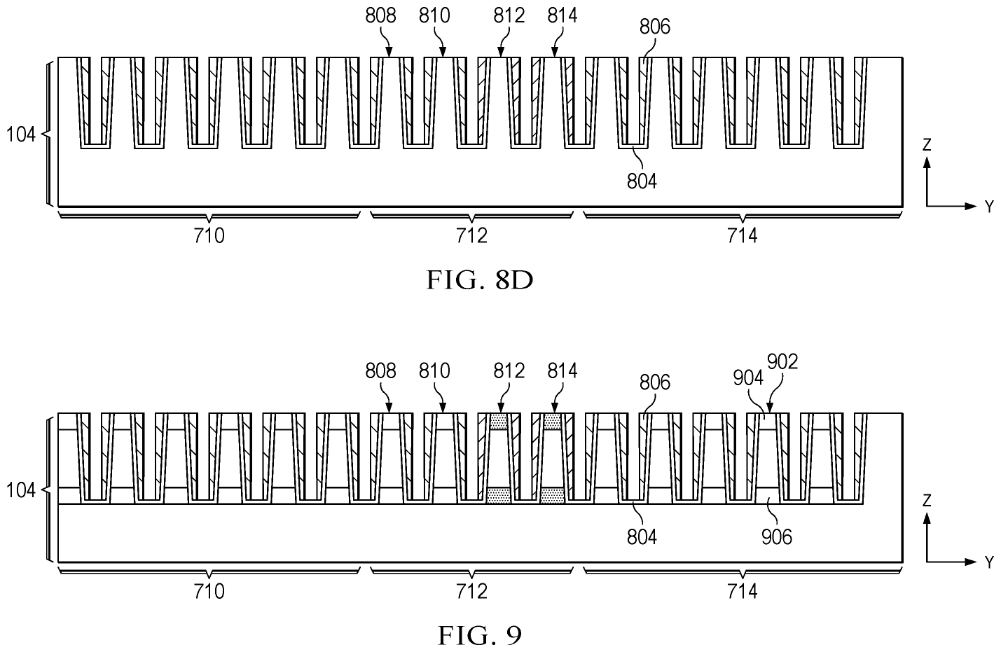

FIGS. 8A-8D illustrate examples of forming gate structures in semiconductor layer 104, according to some aspects of the present disclosure. FIGS. 8A-8B illustrate side view and plan view examples of depositing a dielectric material 802 to fill trenches of semiconductor layer 104, respectively. For example, dielectric material 802 may be silicon oxide or a high-k dielectric material. In some implementations, dielectric material 802 is deposited using one or more thin film deposition processes including, but not limited to, chemical vapor deposition (CVD), physical vapor deposition (PVD), atomic layer deposition (ALD), or any combination thereof. As a result, a gate dielectric layer (such as gate dielectric layer 804 in FIG. 8C) is formed on semiconductor bodies of semiconductor layer 104. The deposition conditions, such as deposition rate and/or time, can be controlled to control the thickness of gate dielectric layer 804.

FIG. 8C illustrates a side view example of depositing a conductive layer on the semiconductor layer 104. One or more gate electrodes may be further formed over the gate dielectric layer 804 to form the gate structure. In some implementations, to form the gate electrode, a conductive layer is deposited over the gate dielectric layer. As illustrated in FIG. 8C, a gate conductive layer 806 is formed over gate dielectric layer 804. In some implementations, gate conductive layer 806 is formed by depositing one or more conductive materials, such as metal and/or metal compounds (e.g., W and TiN), over gate dielectric layer 804 using one or more thin film deposition processes including, but not limited to, CVD, PVD, ALD, or any combination thereof. For example, layers of TiN and W may be sequentially deposited to form gate conductive layer 806. The deposition conditions, such as deposition rate and/or time, can be controlled to control the thickness of gate conductive layer 806. Gate conductive layer 806 can be a continuous layer in the x direction.

FIG. 8D illustrates a side view example of adjusting work functions of different gate electrodes in the semiconductor layer 104. In some implementations, a metal gate doping process is applied to gate electrodes in the semiconductor layer 104 to adjust work functions and threshold voltages for the vertical transistors that are to be made. The adjustment may be based on requirements of the vertical transistors. As shown in FIG. 8D, in region 712 of semiconductor layer 104, semiconductor bodies 808, 810, 812, and 814 may belong to vertical transistors with different performance requirements. For example, semiconductor bodies 808 and 810 belong to two NMOS vertical transistors (such as transistors 210 and 226 of FIG. 2B), and semiconductor bodies 812 and 814 belong to two PMOS vertical transistors (such as transistors 224 and 228 of FIG. 2B). In this example, the gate conductive layers on semiconductor bodies 808, 810, 812, and 814 may doped accordingly, so that the work functions of the gate conductive layers are tuned based on different performance requirements of NMOS and PMOS vertical transistors.

FIG. 9 illustrates an example of forming sources and drains for semiconductor bodies in semiconductor layer 104, according to some aspects of the present disclosure. As illustrated in FIG. 9, for each semiconductor body 902 of semiconductor layer 104, an upper end 904 and a lower end 906 are doped to form a source and a drain. In some implementations, an implantation process and/or thermal diffusion process are performed to dope P-type dopants or N-type dopants to upper end 904 and lower end 906. In some implementations, a silicide layer is formed on upper end 904 and lower end 906 by performing a silicidation process. In some implementations, different semiconductor bodies may be doped with different types of dopants. For example, semiconductor bodies 808 and 810 may belong to NMOS vertical transistors (such as transistors 210 and 226 of FIG. 2B), and semiconductor bodies 812 and 814 belong to PMOS vertical transistors (such as transistors 224 and 228 of FIG. 2B). Thus, semiconductor bodies 808 and 810 are doped with a P type dopant, the sources and drains of semiconductor bodies 808 and 810 are doped with a N type dopant, semiconductor bodies 812 and 814 are doped with the N type dopant, and the sources and drains of semiconductor bodies 812 and 814 are doped with the P type dopant.

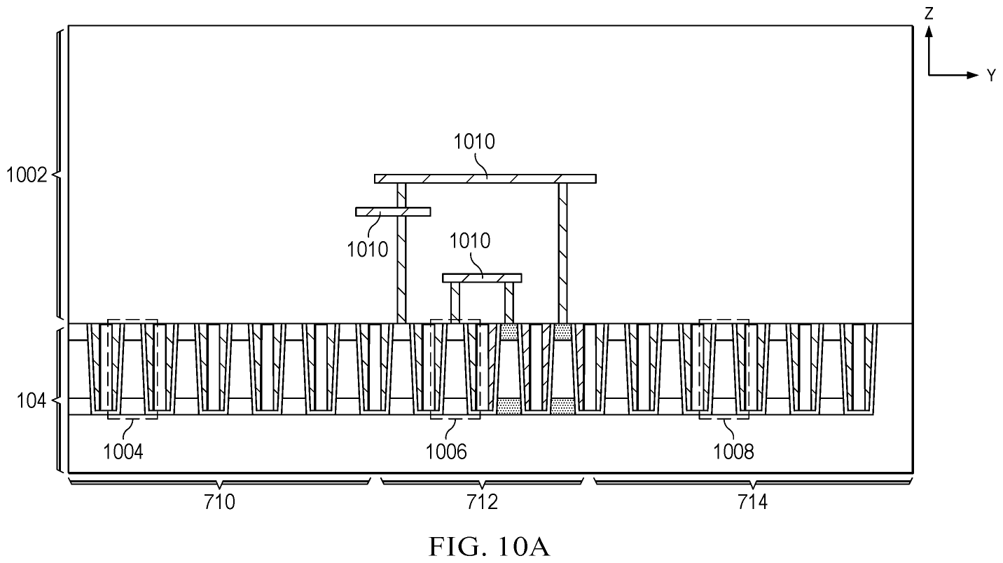

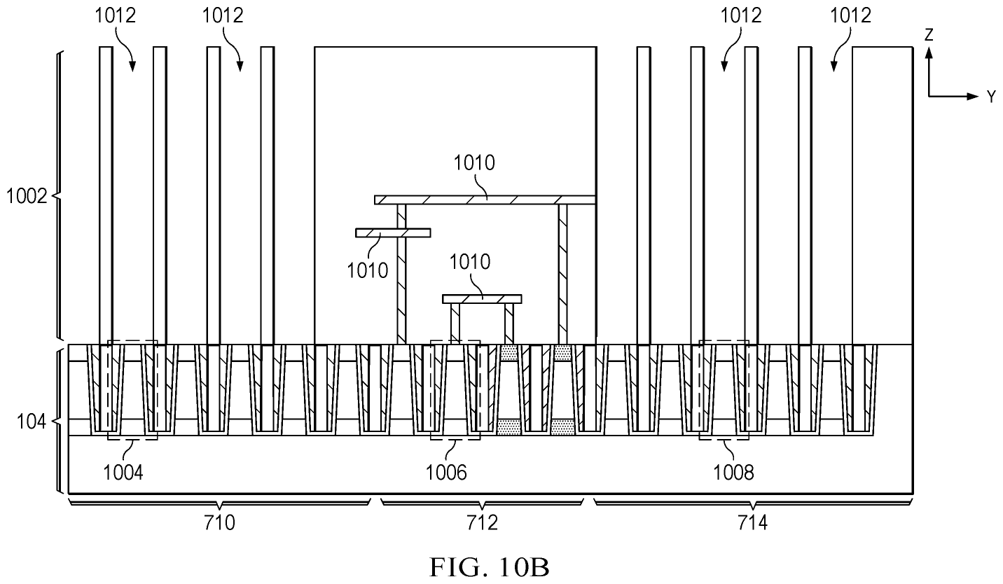

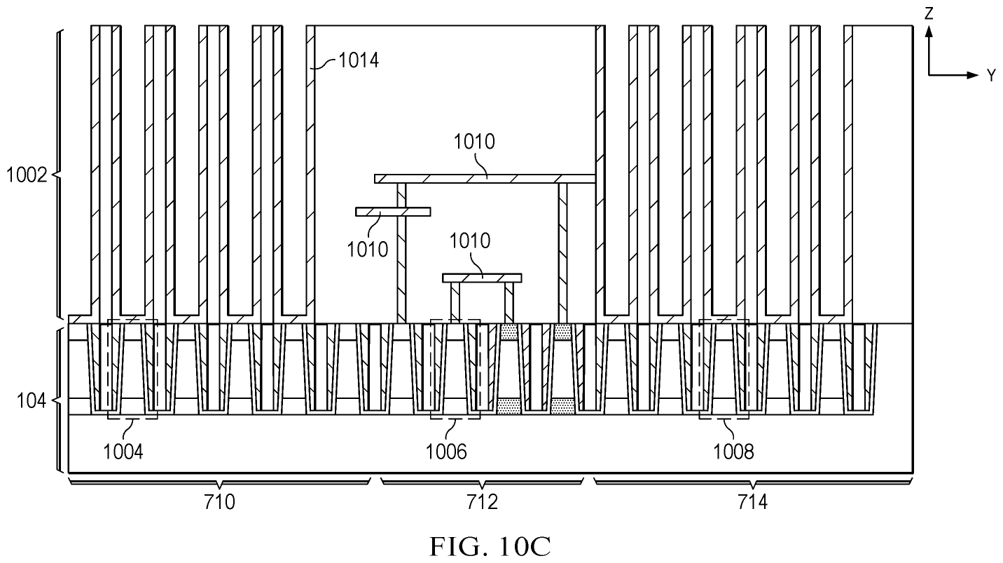

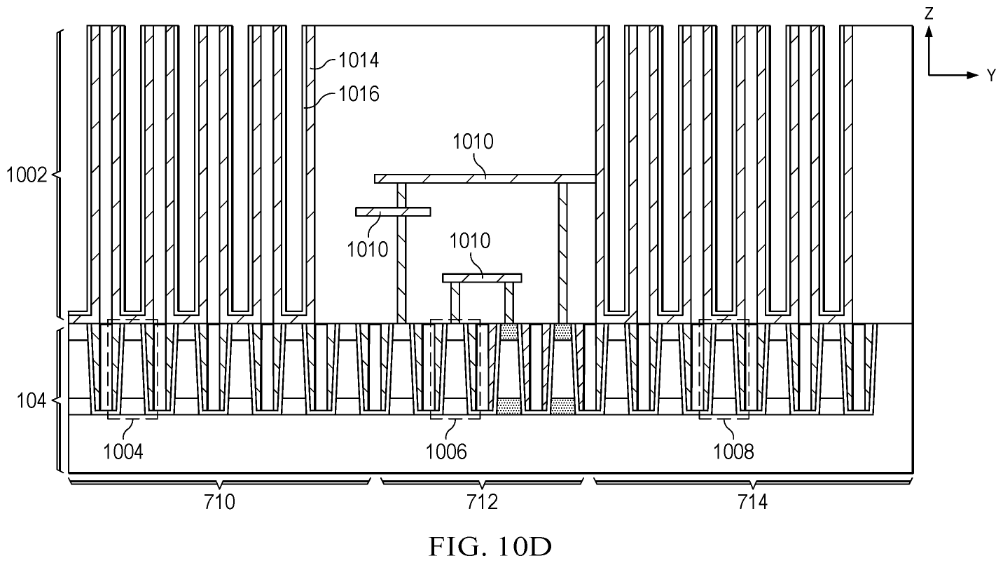

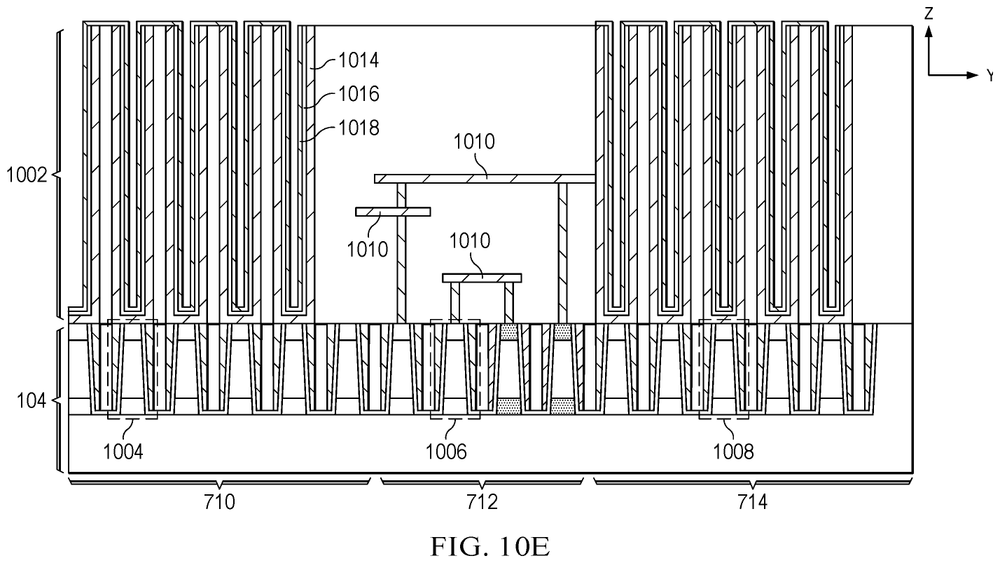

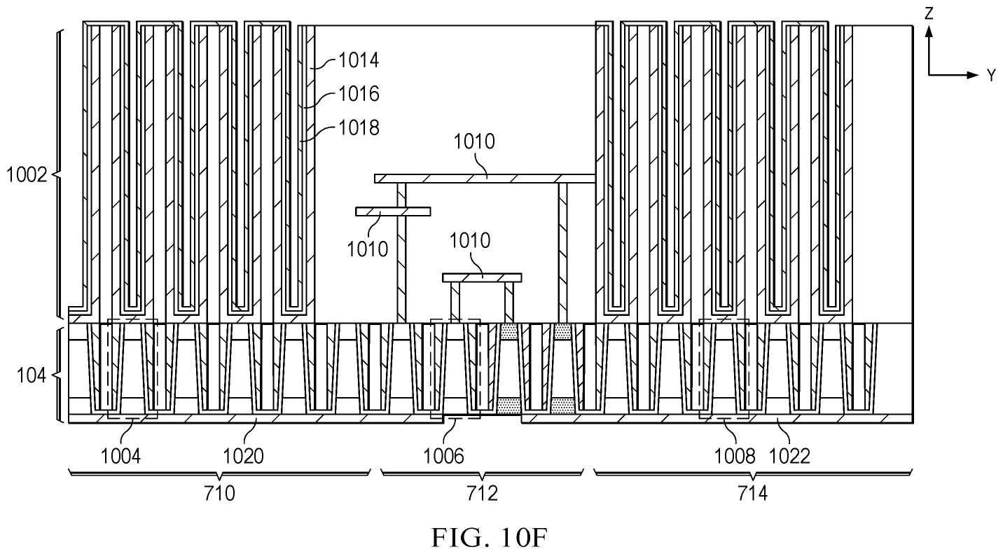

FIGS. 10A-10F illustrate examples of forming storage structures and interconnects in semiconductor layer 104, according to some aspects of the present disclosure. As shown in FIG. 10A, semiconductor layer 104 includes three regions 710, 712, and 714. Region 710 includes vertical transistors 1004, region 712 includes vertical transistors 1006, and region 714 includes vertical transistors 1008. In some implementations, vertical transistors 1004 in region 710 belong to vertical memory cells in a memory cell array (such as memory cell array 108 in FIG. 1 or memory cell array 402 in FIG. 4), and vertical transistors 1008 in region 714 belong to vertical memory cells in another memory cell array (such as memory cell array 404 in FIG. 4). In some implementations, vertical transistors 1006 in region 712 belong to a peripheral circuit (such as vertical circuit 112 in FIG. 1, circuit 410 in FIG. 4, or circuit 504 in FIG. 5A). Vertical transistors 1006 may be coupled to interconnects 1010. For example, interconnects 1010 may connect some transistors in vertical transistors 1006 together. In another example, interconnects 1010 may connect one or more transistors in vertical transistors 1006 to other components of a memory device (not shown in FIG. 10A). Interconnects 1010 may be formed by a back end of line (BEOL) process. For example, a substrate layer 1002 is added on top of semiconductor layer 104 and is in contact with sources or drains (upper ends) of vertical transistors 1006. Interconnects 1010 may include conductive materials deposited by one or more thin film deposition processes including, but not limited to, CVD, PVD, ALD, electroplating, electroless plating, or any combination thereof. Fabrication processes to form the interconnects may include photolithography, chemical-mechanical polishing (CMP), wet/dry etch, or any other suitable processes.

Building vertical memory cells in regions 710 and 714 may include building a storage structure (such as a capacitor) for each vertical transistor (such as vertical transistors 1004 or 1008) in regions 710 and 714. As illustrated by FIG. 10B, a hole 1012 is etched for each of the vertical transistors 1004 and 1008, so that the upper end (a source or a drain) of each vertical transistor is exposed. A conductive layer (also referred to as a lower capacitor electrode) 1014 is formed on the inner surface of each hole 1012 (FIG. 10C). Then, a dielectric layer 1016 is formed on top of the conductive layer 1014 (FIG. 10D). Another conductive layer 1018 is formed on top of the dielectric layer 1016 (FIG. 10E). Each storage structure includes dielectric layer 1016 sandwiched between conductive layer 1014 and conductive layer 1018. Each conductive layer 1014 is coupled to an upper end of a respective vertical transistor (such as vertical transistor 1004 or 1008). In some implementations, each conductive layer 1018 belongs to a common conductive structure coupled to the ground.

In some implementations, lower ends of vertical transistors in regions 710, 712, and 714 are also coupled to interconnects (such as bit lines). As shown in FIG. 10F, a portion of semiconductor layer 104 is removed. For example, the bottom of semiconductor layer 104 may be removed or thinned so that lower ends of vertical transistors in regions 710, 712, and 714 are exposed. A bit line 1020 (such as bit line 508 in FIG. 5A) may be formed to connect vertical transistors 1004 in region 710 (such as a row of vertical transistors of memory cell array 502 in FIG. 5) through their lower ends. Similarly, a bit line 1022 (such as bit line 514 in FIG. 5A) may be formed to connect vertical transistors 1008 in region 714 (such as a row of vertical transistors of memory cell array 506 in FIG. 5A) through their lower ends. Other interconnects coupled to vertical transistors 1006 in region 712 through their lower ends may also be formed (not shown in FIG. 10F).

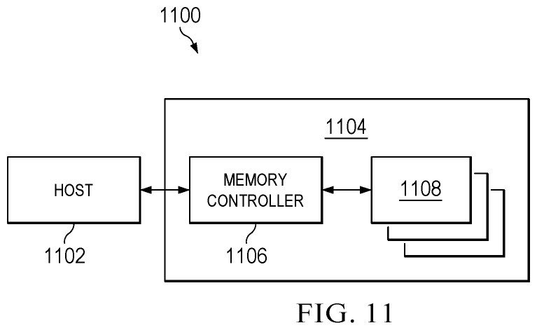

FIG. 11 illustrates a block diagram of a system 1100 having a memory device, according to some aspects of the present disclosure. System 1100 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 11, system 1100 can include a host 1102 and a memory system 1104 having one or more memory devices 1108 and a memory controller 1106. Host 1102 can be a processor of an electronic device, such as a central processing unit (CPU), or a system-on-chip (SoC), such as an application processor (AP). Host 1102 can be configured to send or receive the data to or from memory devices 1108.

Memory device 1108 can be any memory devices disclosed herein, such as memory devices 100, 300, 400, and 500. In some implementations, memory device 1108 includes a memory cell array including a vertical transistor and a peripheral circuit including another vertical transistor, as described above in detail.

Memory controller 1106 is coupled to memory device 1108 and host 1102 and is configured to control memory device 1108, according to some implementations. Memory controller 1106 can manage the data stored in memory device 1108 and communicate with host 1102. Memory controller 1106 can be configured to control operations of memory device 1108, such as read, write, and refresh operations. Memory controller 1106 can also be configured to manage various functions with respect to the data stored or to be stored in memory device 1108 including, but not limited to refresh and timing control, command/request translation, buffer and schedule, and power management. In some implementations, memory controller 1106 is further configured to determines the maximum memory capacity that the computer system can use, the number of memory banks, memory type and speed, memory particle data depth and data width, and other important parameters. Any other suitable functions may be performed by memory controller 1106 as well. Memory controller 1106 can communicate with an external device (e.g., host 1102) according to a particular communication protocol. For example, memory controller 1106 may communicate with the external device through at least one of various interface protocols, such as a universal serial bus (USB) protocol, a Multimedia Card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

As used in this disclosure, the terms “a,” “an,” or “the” are used to include one or more than one unless the context clearly dictates otherwise. The term “or” is used to refer to a nonexclusive “or” unless otherwise indicated. The statement “at least one of A and B” has the same meaning as “A, B, or A and B.” In addition, the phraseology or terminology employed in this disclosure, and not otherwise defined, is for the purpose of description only and not of limitation. Any use of section headings is intended to aid reading of the document and is not to be interpreted as limiting; information that is relevant to a section heading may occur within or outside of that particular section.

As used in this disclosure, the term “about” or “approximately” can allow for a degree of variability in a value or range, for example, within 10%, within 5%, or within 1% of a stated value or of a stated limit of a range.

Values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “0.1% to about 5%” or “0.1% to 5%” should be interpreted to include about 0.1% to about 5%, as well as the individual values (for example, 1%, 2%, 3%, and 4%) and the sub-ranges (for example, 0.1% to 0.5%, 1.1% to 2.2%, 3.3% to 4.4%) within the indicated range. The statement “X to Y” has the same meaning as “about X to about Y,” unless indicated otherwise. Likewise, the statement “X, Y, or Z” has the same meaning as “about X, about Y, or about Z,” unless indicated otherwise.

Particular implementations of the subject matter have been described. Other implementations, alterations, and permutations of the described implementations are within the scope of the following claims as will be apparent to those skilled in the art. While operations are depicted in the drawings or claims in a particular order, such operations are not required be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations are not required in all implementations, and the described components and systems can generally be integrated together or packaged into multiple products.

Accordingly, the previously described example implementations do not define or constrain the present disclosure. Other changes, substitutions, and alterations are also possible without departing from the spirit and scope of the present disclosure.

According to one aspect of the present disclosure, a semiconductor device is disclosed. The semiconductor device comprises a first array of memory cells. Each of the first array of memory cells comprises a first vertical transistor and a storage structure coupled to the first vertical transistor in a first direction. The semiconductor device further comprises a first peripheral circuit adjacent to the first array of memory cells in a second direction perpendicular to the first direction. The first peripheral circuit comprises a second vertical transistor coupled to one of the first array of memory cells through the first vertical transistor of the one of the first array of memory cells.

In some implementations, the first vertical transistor comprises a first semiconductor body extending along the first direction and a first gate structure in contact with at least one side of the first semiconductor body, and the second vertical transistor comprises a second semiconductor body extending along the first direction and a second gate structure in contact with at least one side of the second semiconductor body.

In some implementations, the first gate structure comprises a first conductive layer and a first gate dielectric layer disposed between the first conductive layer and the first semiconductor body in the second direction, and the first semiconductor body comprises a first terminal and a second terminal disposed at two ends of the first semiconductor body in the first direction.

In some implementations, the first terminal is coupled to the storage structure of the same memory cell.

In some implementations, the second gate structure comprises a second conductive layer and a second gate dielectric layer disposed between the second conductive layer and the second semiconductor body in the second direction, and the second semiconductor body comprises a third terminal and a fourth terminal disposed at two ends of the second semiconductor body in the first direction.

In some implementations, material of the first conductive layer and the second conductive layer comprises metal.

In some implementations, width of the first gate dielectric layer is different from width of the second gate dielectric layer in the second direction.

In some implementations, length of the first semiconductor body is different from length of the second semiconductor body in the first direction.

In some implementations, the semiconductor device further comprises a second array of memory cells each comprising a third vertical transistor. The first peripheral circuit is disposed between the first array of memory cells and the second array of memory cells.

In some implementations, the first peripheral circuit comprises at least a portion of a sense amplifier, the sense amplifier comprises a latch circuit, and the latch circuit comprises the second vertical transistor.

In some implementations, the semiconductor device further comprises a first bit line coupled to the first array of memory cells. A row of the first array of memory cells is coupled to the first bit line through the first vertical transistor in each of the row of the first array of memory cells. The second vertical transistor is coupled to the first bit line.

In some implementations, the semiconductor device further comprises a second bit line coupled to the second array of memory cells. A row of the second array of memory cells is coupled to the second bit line through the third vertical transistor in each of the row of the second array of memory cells.

In some implementations, the first peripheral circuit further comprises a fourth vertical transistor in the latch circuit with a different type from the second vertical transistor, and the second vertical transistor and the fourth vertical transistor are coupled to the first bit line.

In some implementations, one of the second vertical transistor and the fourth vertical transistor is a N type transistor, and another one of the second vertical transistor and the fourth vertical transistor is a P type transistor.

In some implementations, the latch circuit further comprises a fifth vertical transistor coupled to the second vertical transistor and a sixth vertical transistor coupled to the fourth vertical transistor. The fifth vertical transistor and the sixth vertical transistor are coupled to the second bit line.

In some implementations, the fifth vertical transistor and the sixth vertical transistor are coupled to the second bit line.

In some implementations, the first peripheral circuit comprises at least a portion of a word line driver.

In some implementations, the semiconductor device further comprises a first word line coupled to the first array of memory cells. A first column of the first array of memory cells is coupled to the first word line through the first gate structure of the first vertical transistor in each of the first column of the first array of memory cells. The second vertical transistor is coupled to the first word line.

In some implementations, the semiconductor device further comprises a second word line coupled to the first array of memory cells. The first peripheral circuit comprises a seventh vertical transistor. A second column of the first array of memory cells is coupled to the second word line through the first gate structure of the first vertical transistor in each of the second column of the first array of memory cells. The seventh vertical transistor is coupled to the second word line.

In some implementations, the semiconductor device further comprises a second peripheral circuit comprising a planar transistor. The second peripheral circuit is coupled to the first array of memory cells and the first peripheral circuit.

According to another aspect of the present disclosure, a memory device is disclosed. The memory device comprises a first semiconductor structure and a second semiconductor structure. The first semiconductor structure comprises a first array of memory cells. Each of the first array of memory cells comprises a first vertical transistor and a storage structure coupled to the first vertical transistor in a first direction. The first semiconductor structure further comprises a first peripheral circuit disposed adjacent to the first array of memory cells in a second direction perpendicular to the first direction. The first peripheral circuit comprises a second vertical transistor coupled to one of the first array of memory cells through the first vertical transistor of the one of the first array of memory cells. The second semiconductor structure comprises a second peripheral circuit coupled to the first semiconductor structure.

In some implementations, the memory device further comprises a bonding interface between the first semiconductor structure and the second semiconductor structure.

In some implementations, the first peripheral circuit comprises a first portion of a sense amplifier, the first portion of the sense amplifier comprises the second vertical transistor, the second peripheral circuit comprises a second portion of the sense amplifier, and the second portion of the sense amplifier comprises a planar transistor.

In some implementations, the first peripheral circuit comprises a first portion of a sense amplifier, the first portion of the sense amplifier comprises the second vertical transistor, the second peripheral circuit comprises a portion of a word line driver, and the portion of the word line driver comprises a planar transistor.

According to another aspect of the present disclosure, a semiconductor device is disclosed. The semiconductor device comprises a first array of memory cells in a first array region.

Each of the first array of memory cells comprises a first vertical transistor extending along a first direction. The semiconductor device further comprises a first peripheral circuit disposed in a circuit region adjacent to the first array region in a second direction perpendicular to the first direction. The first peripheral circuit comprises a second vertical transistor extending along the first direction and coupled to one of the first array of memory cells through the first vertical transistor of the one of the first array of memory cells.

In some implementations, the semiconductor device further comprises a second array of memory cells in a second array region. The first peripheral circuit is disposed between the first array of memory cells and the second array of memory cells.

In some implementations, the first peripheral circuit comprises at least a portion of a sense amplifier, and the portion of the sense amplifier comprises the second vertical transistor.

In some implementations, the portion of the sense amplifier further comprises a third vertical transistor, a fourth vertical transistor coupled to the second vertical transistor, and a fifth vertical transistor coupled to the third vertical transistor, the second vertical transistor and the fourth vertical transistor are of a first type, and the third vertical transistor and the fifth vertical transistor are of a second type.

In some implementations, one of the second vertical transistor and the third vertical transistor is a N type transistor, and another one of the second vertical transistor and the third vertical transistor is a P type transistor.

In some implementations, the semiconductor device further comprises a first bit line coupled to the first array of memory cells. A row of the first array of memory cells is coupled to the first bit line through the first vertical transistor in each of the row of the first array of memory cells. The second vertical transistor and the third vertical transistor are coupled to the first bit line. The semiconductor device further comprises a second bit line coupled to the second array of memory cells. Each of the second array of memory cells comprises a sixth vertical transistor extending along a first direction. A row of the second array of memory cells is coupled to the second bit line through the sixth vertical transistor in each of the row of the second array of memory cells. The fourth vertical transistor and the fifth vertical transistor are coupled to the second bit line.

In some implementations, each of the row of the first array of memory cells comprises a first storage structure coupled to a respective first vertical transistor. The respective first vertical transistor is located between the first storage structure and the first bit line. Each of the row of the second array of memory cells comprises a second storage structure coupled to a respective sixth vertical transistor. The respective sixth vertical transistor is located between the second storage structure and the second bit line.

In some implementations, the first peripheral circuit comprises at least a portion of a word line driver.

In some implementations, the first vertical transistor comprises a first semiconductor body extending along the first direction and a first gate structure in contact with at least one side of the first semiconductor body, and the second vertical transistor comprises a second semiconductor body extending along the first direction and a second gate structure in contact with at least one side of the second semiconductor body.

In some implementations, the first semiconductor body and the second semiconductor body are formed in a same process.

In some implementations, the semiconductor device further comprises a second peripheral circuit comprising a planar transistor. The second peripheral circuit is coupled to the first peripheral circuit.

According to another aspect of the present disclosure, a method for forming a semiconductor device is disclosed. The method comprises forming a first semiconductor body of a first vertical transistor in a first region of a semiconductor layer and a second semiconductor body of a second vertical transistor in a second region adjacent to the first region of the semiconductor layer. The first semiconductor body and the second semiconductor body are formed on a first side of the semiconductor layer. The method further comprises forming a first gate structure of the first vertical transistor and a second gate structure of the second vertical transistor. The first gate structure is in contact with at least one side of the first semiconductor body. The second gate structure is in contact with at least one side of the second semiconductor body. The method further comprises forming a first storage structure above and in contact with a first end of the first semiconductor body.

In some implementations, the method further comprises forming a third semiconductor body of a third vertical transistor and forming a third gate structure in contact with at least one side of the third semiconductor body.

In some implementations, the method further comprises doping the semiconductor layer in the first region with a P type dopant, doping the semiconductor layer in a first part of the second region with the P type dopant to form the second semiconductor body, and doping the semiconductor layer in a second part of the second region with an N type dopant to form the third semiconductor body.

In some implementations, the method further comprises removing a portion of the semiconductor layer from a second side to expose a second end of the first semiconductor body opposite to the first end of the first semiconductor body, a first end of the second semiconductor body, and a first end of the third semiconductor body. The method further comprises forming a first bit line in contact with the second end of the first semiconductor body, a second end of the second semiconductor body, and a second end of the third semiconductor body. The first end of the second semiconductor body is coupled to a fourth vertical transistor. The first end of the third semiconductor body coupled to a fifth vertical transistor.

In some implementations, the method further comprises forming a fourth semiconductor body of a sixth vertical transistor in a third region. The second region is between the first region and the third region. The method further comprises forming a fourth gate structure in contact with at least one side of the fourth semiconductor body. The method further comprises forming a second storage structure above and in contact with a first end of the fourth semiconductor body.

In some implementations, the method further comprises removing a portion of the semiconductor layer from a second side to expose a second end of the fourth semiconductor body opposite to the first end of the fourth semiconductor body and forming a second bit line in contact with the second end of the fourth semiconductor body.

According to another aspect of the present disclosure, a method for forming a semiconductor device is disclosed. The method comprises providing a semiconductor layer. The semiconductor layer comprises a first region and a second region adjacent to the first region in a first direction. The method further comprises forming a first vertical transistor extending along a second direction perpendicular to the first direction in the first region of the semiconductor layer. The method further comprises forming a second vertical transistor in the second region of the semiconductor layer. The method further comprises forming a first storage structure coupled to the first vertical transistor.

In some implementations, the method further comprises doping the first region of the semiconductor layer with ions of a first type and doping the second region of the semiconductor layer with at least one of ions of the first type or ions of a second type.

In some implementations, the forming the first vertical transistor in the first region comprises forming a first semiconductor body extending along the second direction and forming a first gate structure in contact with at least one side of the first semiconductor body. The first gate structure comprise a first conductive layer and a first gate dielectric layer disposed between the first conductive layer and the first semiconductor body in the first direction.

In some implementations, the forming the second vertical transistor in the second region comprises forming a second semiconductor body extending along the second direction in a same process of forming the first semiconductor body and forming a second gate structure in contact with at least one side of the second semiconductor body in a same process of forming the first gate structure. The second gate structure comprises a second conductive layer and a second gate dielectric layer disposed between the second conductive layer and the second semiconductor body in the first direction.

In some implementations, the method further comprises thinning the semiconductor layer to expose a first end of the first semiconductor body and a first end of the second semiconductor body and forming a first bit line in contact with the first end of the first semiconductor body and the first end of the second semiconductor body.

In some implementations, the forming a first storage structure coupled to the first vertical transistor comprises forming the first storage structure in contact with a second end of the first semiconductor body opposite to a first end of the first semiconductor body.

In some implementations, the method further comprises forming a third vertical transistor in the second region of the semiconductor layer. The third vertical transistor is of a different type from the second vertical transistor. The third vertical transistor comprises a third semiconductor body extending along the second direction. The first bit line is in contact with a first end of the third semiconductor body.

In some implementations, the method further comprises forming a fourth vertical transistor and a fifth vertical transistor in the second region. A second end of the second semiconductor body opposite to the first end of the second semiconductor body is coupled to the fourth vertical transistor. A second end of the third semiconductor body opposite to the first end of the third semiconductor body is coupled to the fifth vertical transistor.

In some implementations, the semiconductor layer comprises a third region. The second region is between the first region and the third region. The method further comprises forming a sixth vertical transistor in the third region of the semiconductor layer. The sixth vertical transistor comprises a sixth semiconductor body extending along the second direction. The method further comprises forming a second storage structure coupled to a first end of the sixth semiconductor body.

In some implementations, the method further comprises forming a second bit line in contact with a second end of the sixth vertical transistor opposite to the first end of the sixth semiconductor body.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described example implementations, but should be defined only in accordance with the following claims and their equivalents. Accordingly, other implementations also are within the scope of the claims.

What is claimed is:

1. A semiconductor device, comprising:
a first array of memory cells, wherein each of the first array of memory cells comprises a first vertical transistor and a storage structure coupled to the first vertical transistor in a first direction; and
a first peripheral circuit adjacent to the first array of memory cells in a second direction perpendicular to the first direction, wherein the first peripheral circuit comprises a second vertical transistor coupled to one of the first array of memory cells through the first vertical transistor of the one of the first array of memory cells.

2. The semiconductor device of claim 1, wherein:
the first vertical transistor comprises a first semiconductor body extending along the first direction and a first gate structure in contact with at least one side of the first semiconductor body; and
the second vertical transistor comprises a second semiconductor body extending along the first direction and a second gate structure in contact with at least one side of the second semiconductor body.

3. The semiconductor device of claim 2, wherein:
the first gate structure comprises a first conductive layer and a first gate dielectric layer disposed between the first conductive layer and the first semiconductor body in the second direction; and
the first semiconductor body comprises a first terminal and a second terminal disposed at two ends of the first semiconductor body in the first direction.

4. The semiconductor device of claim 3, wherein:
the second gate structure comprises a second conductive layer and a second gate dielectric layer disposed between the second conductive layer and the second semiconductor body in the second direction; and
width of the first gate dielectric layer is different from width of the second gate dielectric layer in the second direction.

5. The semiconductor device of claim 2, wherein length of the first semiconductor body is different from length of the second semiconductor body in the first direction.

6. The semiconductor device of claim 1, further comprising a second array of memory cells each comprising a third vertical transistor, wherein the first peripheral circuit is disposed between the first array of memory cells and the second array of memory cells.

7. The semiconductor device of claim 6, wherein the first peripheral circuit comprises at least a portion of a sense amplifier, the sense amplifier comprises a latch circuit, and the latch circuit comprises the second vertical transistor.

8. The semiconductor device of claim 7, further comprising a first bit line coupled to the first array of memory cells, wherein a row of the first array of memory cells is coupled to the first bit line through the first vertical transistor in each of the row of the first array of memory cells, and the second vertical transistor is coupled to the first bit line.

9. The semiconductor device of claim 8, further comprising a second bit line coupled to the second array of memory cells, wherein a row of the second array of memory cells is coupled to the second bit line through the third vertical transistor in each of the row of the second array of memory cells.

10. The semiconductor device of claim 9, wherein the first peripheral circuit further comprises a fourth vertical transistor in the latch circuit with a different type from the second vertical transistor, and the second vertical transistor and the fourth vertical transistor are coupled to the first bit line.

11. The semiconductor device of claim 10, wherein the latch circuit further comprises a fifth vertical transistor coupled to the second vertical transistor and a sixth vertical transistor coupled to the fourth vertical transistor, wherein the fifth vertical transistor and the sixth vertical transistor are coupled to the second bit line.

12. The semiconductor device of claim 1, further comprising a second peripheral circuit comprising a planar transistor, wherein the second peripheral circuit is coupled to the first array of memory cells and the first peripheral circuit.

13. A semiconductor device, comprising:
a first array of memory cells in a first array region, wherein each of the first array of memory cells comprises a first vertical transistor extending along a first direction; and
a first peripheral circuit disposed in a circuit region adjacent to the first array region in a second direction perpendicular to the first direction, wherein the first peripheral circuit comprises a second vertical transistor extending along the first direction and coupled to one of the first array of memory cells through the first vertical transistor of the one of the first array of memory cells.

14. The semiconductor device of claim 13, further comprising a second array of memory cells in a second array region, wherein the first peripheral circuit is disposed between the first array of memory cells and the second array of memory cells.

15. A method for forming a semiconductor device, comprising:
forming a first semiconductor body of a first vertical transistor in a first region of a semiconductor layer and a second semiconductor body of a second vertical transistor in a second region adjacent to the first region of the semiconductor layer, wherein the first semiconductor body and the second semiconductor body are formed on a first side of the semiconductor layer;
forming a first gate structure of the first vertical transistor and a second gate structure of the second vertical transistor, wherein the first gate structure is in contact with at least one side of the first semiconductor body, the second gate structure is in contact with at least one side of the second semiconductor body; and
forming a first storage structure above and in contact with a first end of the first semiconductor body.

16. The method of claim 15, further comprising:
forming a third semiconductor body of a third vertical transistor; and
forming a third gate structure in contact with at least one side of the third semiconductor body.

17. The method of claim 16, further comprising:
doping the semiconductor layer in the first region with a P type dopant;
doping the semiconductor layer in a first part of the second region with the P type dopant to form the second semiconductor body; and
doping the semiconductor layer in a second part of the second region with an N type dopant to form the third semiconductor body.

18. The method of claim 16, further comprising:
removing a portion of the semiconductor layer from a second side to expose a second end of the first semiconductor body opposite to the first end of the first semiconductor body, a first end of the second semiconductor body, and a first end of the third semiconductor body; and
forming a first bit line in contact with the second end of the first semiconductor body, a second end of the second semiconductor body, and a second end of the third semiconductor body, wherein the first end of the second semiconductor body is coupled to a fourth vertical transistor, and wherein the first end of the third semiconductor body coupled to a fifth vertical transistor.

19. The method of claim 16, further comprising:
forming a fourth semiconductor body of a sixth vertical transistor in a third region, the second region is between the first region and the third region;
forming a fourth gate structure in contact with at least one side of the fourth semiconductor body; and
forming a second storage structure above and in contact with a first end of the fourth semiconductor body.

20. The method of claim 19, further comprising:
removing a portion of the semiconductor layer from a second side to expose a second end of the fourth semiconductor body opposite to the first end of the fourth semiconductor body; and
forming a second bit line in contact with the second end of the fourth semiconductor body.
